(19) United States
(12) Patent Application Publication
(10) Pub. No.: US 2022/0003876 A1
(43) Pub. Date: Jan. 6, 2022

(54) DISTANCE IMAGE OBTAINING METHOD AND DISTANCE DETECTION DEVICE

(71) Applicant: Panasonic Intellectual Property Management Co., Ltd., Osaka (JP)

(72) Inventors: Shigetaka KASUGA, Osaka (JP); Shinzo KOYAMA, Osaka (JP); Masaki TAMARU, Kyoto (JP); Hiroshi KOSHIDA, Osaka (JP); Yugo NOSE, Kyoto (JP); Masato TAKEMOTO, Osaka (JP)

(21) Appl. No.: 17/480,475

(22) Filed: Sep. 21, 2021

Related U.S. Application Data
(63) Continuation of application No. PCT/JP2020/012645, filed on Mar. 23, 2020.

(30) Foreign Application Priority Data
Mar. 26, 2019 (JP) 2019-058990

(51) Int. Cl. G01S 17/894; G01S 17/10; G01S 7/4865; H01L 31/107

(52) U.S. Cl. CPC G01S 17/894; H01L 31/107; G01S 7/4865; G01S 17/10

(57) ABSTRACT

A distance-image obtaining method includes: (A) setting a plurality of distance-divided segments in a depth direction, and (B) obtaining a distance image based on each of the plurality of distance-divided segments set. The obtaining of the distance image includes: obtaining a plurality of distance images by imaging two or more of the plurality of distance-divided segments, to obtain a first distance image group; and obtaining a plurality of distance images by imaging distance-divided segments, among the plurality of distance-divided segments, in a phase different from a phase of the two or more of the plurality of distance-divided segments, to obtain a second distance image group.

### CROSS REFERENCE TO RELATED APPLICATIONS

This is a continuation application of PCT International Application No. PCT/JP2020/012645 filed on Mar. 23, 2020, designating the United States of America, which is based on and claims priority of Japanese Patent Application No. 2019-058990 filed on Mar. 26, 2019. The entire disclosures of the above-identified applications, including the specifications, drawings and claims are incorporated herein by reference in their entirety.

### FIELD

The present disclosure relates to a distance image obtaining method and a distance detection device.

### BACKGROUND

In recent years, a distance image sensor (i.e., a distance detection device) for obtaining a distance image in real time has been noticed in many fields, such as a robotics field, an automobile field, a security field, and an amusement field. Here, the distance image corresponds to three-dimensional information of a target in a space, and is composed of pixel values indicating a distance to the target (i.e., an object).

As a distance measurement method for obtaining a distance image, a method of detecting a distance to a target using a time-of-flight (TOF) system has been known. For example, Patent Literature (PTL) 1 discloses a device that applies light to a target to detect three-dimensional information (three-dimensional shape) of the target.

### CITATION LIST

### Patent Literature

PTL 1: Japanese Unexamined Patent Application Publication No. 2001-116516

### SUMMARY

### Technical Problem

A distance image sensor used in automobiles and so on is typically required to quickly obtain information regarding a distance to a target in a broad range from a short distance to a long distance in front of the distance image sensor. At the same time, the distance image sensor is also required to measure the distance strictly, i.e., to have high-accurate resolution in measuring a distance.

In view of the above, an object of the present disclosure is to provide a distance image obtaining method and a distance detection device, in which information regarding a distance to a target is quickly obtained in a broad range from a short distance to a long distance with high-accurate resolution.

### Solution to Problem

A distance-image obtaining method according to an aspect of the present disclosure includes: (A) setting a plurality of distance-divided segments in a depth direction; and (B) obtaining a distance image based on each of the plurality of distance-divided segments set. (B) includes: (B-1) obtaining a plurality of distance images by imaging two or more of the plurality of distance-divided segments, to obtain a first distance image group; and (B-2) obtaining a plurality of distance images by imaging distance-divided segments, among the plurality of distance-divided segments, in a phase different from a phase of the two or more of the plurality of distance-divided segments, to obtain a second distance image group.

A distance detection device according to another aspect of the present disclosure includes: an image sensor in which pixels each having an avalanche photo diode (APD) are arranged in a two-dimensional manner; a light source that emits emission light to a target to be imaged; a calculator that processes images obtained by the image sensor; a controller that controls the light source, the image sensor, and the calculator; a compositor that generates a composite image by combining the images processed by the calculator; and an outputter that adds predetermined information to the composite image, and outputs the composite image. The controller: sets a plurality of distance-divided segments in a depth direction; and causes the light source, the image sensor, and the calculator to perform obtainment of a first distance image group including a plurality of distance images obtained by imaging a part of the plurality of distance-divided segments set, and to perform obtainment of a second distance image group including a plurality of distance images by imaging distance-divided segments, among the plurality of distance-divided segments set, in a phase different from a phase of the part of the plurality of distance-divided segments.

### Advantageous Effects

In the distance-image obtaining method and distance detection device according to an aspect of the present disclosure, information regarding a distance to a target can be quickly obtained with high-accurate resolution in a broad range from a short distance to a long distance.

### BRIEF DESCRIPTION OF DRAWINGS

These and other advantages and features will become apparent from the following description thereof captured in conjunction with the accompanying Drawings, by way of non-limiting examples of embodiments disclosed herein.

FIG. 1 is a block diagram showing a configuration of a distance detection device according to Embodiment 1.

FIG. 2 is a block diagram showing a configuration of a camera according to Embodiment 1.

FIG. 3A is a circuit diagram showing a configuration of a pixel according to Embodiment 1.

FIG. 3B is a circuit diagram showing a configuration of a correlated double sampling (CDS) circuit according to Embodiment 1.

FIG. 3C is a circuit diagram showing a configuration of an analog-to-digital converter (ADC) circuit according to Embodiment 1.

FIG. 4A is a diagram showing an example of timing of distance measurement processing in a first subframe in group A in the distance detection device according to Embodiment 1.

FIG. 4B is a diagram showing the first subframe image according to Embodiment 1.

FIG. 5A is a diagram showing an example of timing of the distance measurement processing in a third subframe in group A in the distance detection device according to Embodiment 1.

FIG. 5B is a diagram showing the third subframe image according to Embodiment 1.

FIG. 6A is a diagram showing an example of timing of the distance measurement processing in a fifth subframe in group A in the distance detection device according to Embodiment 1.

FIG. 6B is a diagram showing the fifth subframe image according to Embodiment 1.

FIG. 7 is a diagram showing a composed distance image according to Embodiment 1.

FIG. 8 is a flowchart showing an example of distance image generation processing in the distance detection device according to Embodiment 1.

FIG. 9A is a pattern diagram for describing an example of a first distance image according to Embodiment 1.

FIG. 9B is a flowchart typically showing flow of generating the first distance image according to Embodiment 1.

FIG. 9C is a pattern diagram for describing an example of a second distance image according to Embodiment 1.

FIG. 9D is a diagram showing a first example of the relationship in distance measurement segments in each frame according to Embodiment 1.

FIG. 9E is a diagram showing a second example of the relationship in the distance measurement segments in each frame according to Embodiment 1.

FIG. 10A is a pattern diagram for describing another example of the first distance image according to Embodiment 1.

FIG. 10B is a pattern diagram for describing another example of the second distance image according to Embodiment 1.

FIG. 10C is a diagram showing a third example of the relationship in distance measurement segments in each frame according to Embodiment 1.

FIG. 10D is a diagram showing a fourth example of the relationship in distance measurement segments in each frame according to Embodiment 1.

FIG. 11 is a block diagram showing a configuration of a distance detection device according to Embodiment 2.

FIG. 12 is a block diagram showing a configuration of an image sensor according to Embodiment 2.

FIG. 13 is a circuit diagram showing a configuration of a pixel according to Embodiment 2.

FIG. 14 is a diagram showing timing of distance detection processing in the distance detection device according to Embodiment 2.

FIG. 15 is a pattern diagram for describing a distance image in a single frame according to Embodiment 2.

FIG. 16 is a flowchart showing an example of distance image generation processing in the distance detection device according to Embodiment 2.

FIG. 17A is a pattern diagram for describing an example of a first distance image according to Embodiment 2.

FIG. 17B is a flowchart typically showing flow of generating the first distance image according to Embodiment 2.

FIG. 17C is a pattern diagram for describing an example of a second distance image according to Embodiment 2.

FIG. 18A is a pattern diagram for describing another example of the first distance image according to Embodiment 2.

FIG. 18B is a pattern diagram for describing another example of the second distance image according to Embodiment 2.

### DESCRIPTION OF EMBODIMENTS

Hereinafter, embodiments of the present disclosure are described in detail, with reference to the drawings. It should be noted that every embodiment described below shows a specific example of the present disclosure. Numerical values, shapes, materials, structural components, arrangement positions and connection forms of the structural components, steps, order of the steps, and so on described in the following embodiments are examples, and are not intended to limit the present disclosure. This disclosure is limited only by the scope of claims. Thus, structural components not described in independent claims will be described, among structural components in the following embodiments.

Each drawing is a pattern diagram and is not always exactly illustrated. In addition, duplicate descriptions for substantially the same configuration may be omitted.

In the description of the specification, terms indicating relationship between components, such as “equal to”, and numerical values as well as numerical ranges are not expressions that express strict meanings only, but express substantially equivalent ranges including differences at a level of several percent, for example.

### Embodiment 1

### [1-1. Configuration]

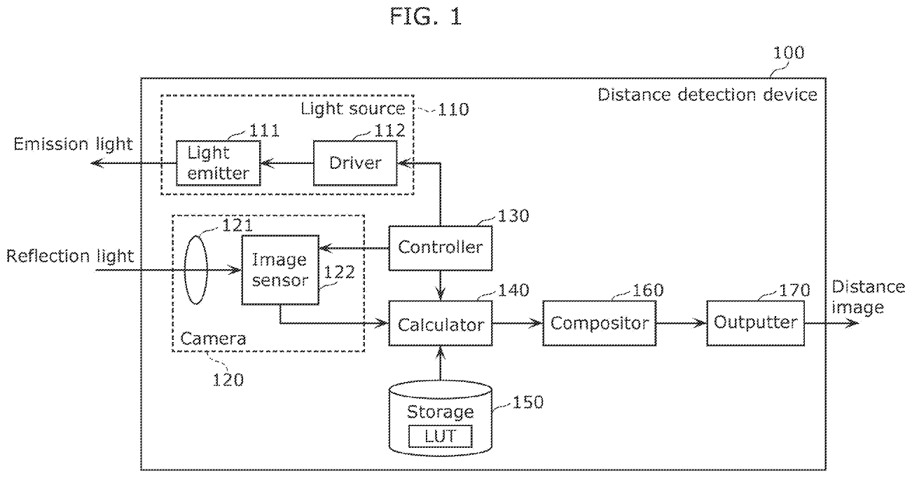

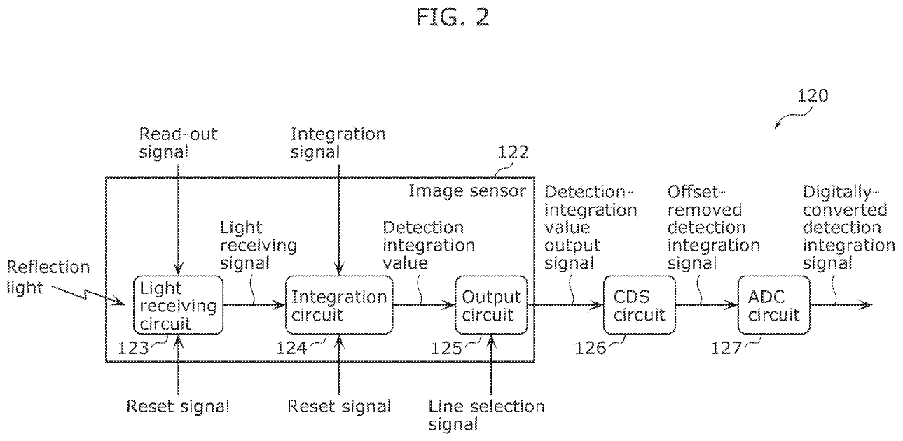

A configuration of a distance detection device according to the present embodiment is described with reference to FIGS. 1 to 3B. FIG. 1 is a block diagram showing a configuration of distance detection device 100 according to the present embodiment. FIG. 2 is a block diagram showing a configuration of camera 120 according to the present embodiment.

As shown in FIG. 1, distance detection device 100 generates, with a time-of-flight (TOF) system, a distance image indicating a distance to a target positioned within a distance range that is subjected to measurement. Distance detection device 100 can be used for a sensor for three-dimensional images, for example. Distance detection device 100 includes light source 100, camera 120, controller 130, calculator 140, storage 150, compositor 160, and outputter 170.

Light source 110 emits emission light. Light source 110 includes light emitter 111 and driver 112. Light emitter 111 emits the emission light (e.g., light pulses). Light emitter 111 is a laser diode (LD) or a light emitting diode (LED), for example. Driver 112 controls timing at which electric power is supplied to light emitter 111, to thereby control the emittance of light emitter 111.

Camera 120 receives reflection light generated by reflection of the emission light on a target, to generate detection signals. In the present embodiment, camera 120 is provided with an avalanche photodiode (APD) that is a light receiving element using avalanche multiplication. Camera 120 includes lens 121, image sensor 122, correlated double sampling (CDS) circuit 126, and ADC circuit 127, as shown in FIGS. 1 and 2.

Lens 121 converges the reflection light into image sensor 122. Image sensor 122 receives the reflection light and outputs detection integration value corresponding to light quantity of the received light. Image sensor 122 is a complementary metal-oxide-semiconductor (CMOS) image sensor that has a light receiver in which pixels each having the APD are arranged in a two-dimensional manner.

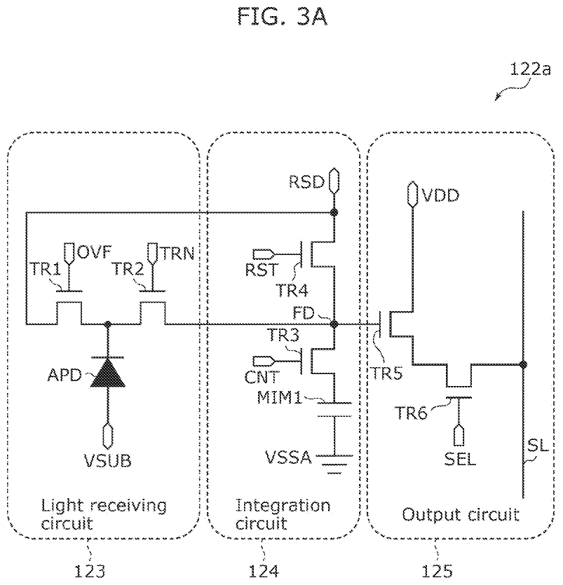

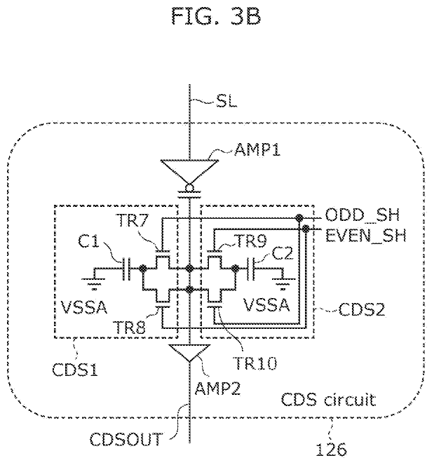

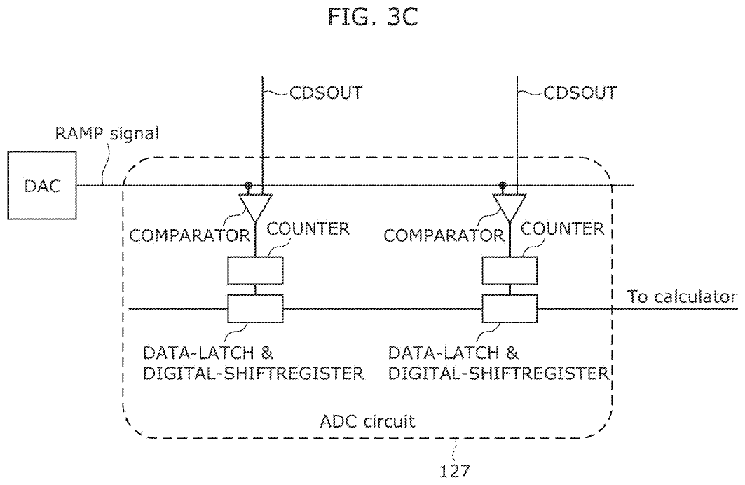

CDS circuit 126 is a circuit for removing offset components contained in the detection integration values outputted from pixel 122a. The offset components may have different values depending on pixel 122a. ADC circuit 127 converts, to a digital signal, an analog signal (a detection integration value from which an offset component is removed) outputted from CDS circuit 126. ADC circuit 127 may use a single slope system, for example, so as to generate a digital signal (e.g., a digitally-converted detection integration signal) corresponding to the quantity of light received by pixel 122a. In the single slope system, the analog signal (e.g., an offset-removed detection integration signal) CDSOUT outputted from CDS circuit 126 (see FIG. 3B) is compared with a RAMP signal and converted to a digital signal. Hereinafter, analog signal CDSOUT may be referred to as output signal CDSOUT.

Details of image sensor 122, CDS circuit 126, and ADC circuit 127 are described later. Although distance detection device 100 includes CDS circuit 126 in the present embodiment, distance detection device 100 may not include CDS circuit 126. In addition, ADC circuit 127 may be included in calculator 140.

Controller 130 controls light-emission timing in light source 110 and light-receiving timing (exposure period) in camera 120. Controller 130 sets distance measurement ranges different from one another in a first frame and a second frame that is subsequent to the first frame. The first frame and the second frame are, for example, temporally adjacent to each other among a plurality of frames.

Controller 130 sets a distance measurement range to each of a plurality of subframes which are included in subframes of group A, and are prepared by dividing the first frame. The distance measurement ranges to be set are different from one another and have no distance-continuity to one another, for example. Controller 130 controls light-emission timing in light source 110 and light-receiving timing in camera 120 so that distance measurement is performed in the set distance measurement range in each of the subframes in group A. The subframe group in group A are composed of, for example, a part of distance measurement segments among a plurality of the distance measurement segments prepared by dividing the first frame.

Here, no distance continuity means that the distance measurement ranges of the respective subframes in group A do not continue. For example, no distance continuity means that at least a part of the distance measurement range in one of two subframes in group A and that in the other subframe do not overlap. In other words, the distance measurement range in one of two subframes and that in the other subframe are separated from each other in terms of distance. A distance measurement range between the distance measurement range in the one of the two subframes and that in the other subframe is to be measured in a frame other than the first frame (a second frame in the present embodiment), and thus undergoes the distance measurement in a plurality of subframes set in the second frame.

Controller 130 sets a distance measurement range that is not set in the first frame to each of a plurality of subframes which are included in subframes in group B and are prepared by dividing the second frame. Controller 130 respectively sets to the subframes in group B, distance measurement ranges that are not set in the first frame, are different from one another, and have no continuity in terms of distance. Furthermore, controller 130 controls the light-emission timing in light source 110 and the light-receiving timing in camera 120 so that the distance measurement is performed in the set distance measurement range in each of the subframes in group B. The subframes in group B may be composed of, for example, a part of the distance measurement segments among a plurality of distance measurement segments (subframes) prepared by dividing the second frame. The subframes in group B may include subframes corresponding to segments obtained by shifting a plurality of distance measurement segments in group A in the depth direction, for example.

Controller 130 controls light source 110 and camera 120 for each of the distance measurement ranges, to thereby cause camera 120 to generate the digitally-converted detection integration signal (detection signal) for generating a distance image that indicates a distance to a target in each of the distance measurement ranges.

In the present embodiment, controller 130 exemplary sets distance measurement ranges so that the distance measurement ranges in the first frame and the distance measurement ranges in the second frame define the distance continuity. Controller 130 may not improve a frame rate of image sensor 122 in terms of hardware, but may set a distance range of each of three or more frames so that the three or more frames have the distance continuity, from a viewpoint that the distance measurement range per hour is apparently broadened for performing the distance measurement in a broad range from a short distance to a long distance in a short period of time. Details of the distance measurement ranges set by controller 130 are described later.

Calculator 140 serves as a processor that determines presence/absence of an object, based on a detection-integration value output signal (voltage signal) outputted from output circuit 125, for each of the subframes in group A and each of the subframes in group B. In the present embodiment, calculator 140 determines the presence/absence of an object based on a digitally-converted detection integration signal obtained by performing predetermined processing (e.g., correlated double sampling processing that is described later) on the detection-integration value output signal. Calculator 140 may determine the presence/absence of the object by comparing the digitally-converted detection integration signal with a predetermined threshold value (e.g., a look up table (LUT) stored in storage 150). If a value of the digitally-converted detection integration signal (e.g., a voltage value) is greater than or equal to the predetermined threshold value, calculator 140 may determine that the object exists within a concerned distance measurement range (a concerned subframe). If the value of the digitally-converted detection integration signal is less than the predetermined threshold value, calculator 140 may determine that no object exists within the distance measurement range (the subframe). Here, the value of the digitally-converted detection integration signal corresponds to a detection integration value based on the frequency of receiving of the reflection light by the APD.

Calculator 140 identifies subframe numbers (subframe Nos.) for the respective subframes, and determines the presence/absence of an object for each pixel in the subframes. Then, calculator 140 outputs, to compositor 160, the subframe number and a determination result regarding the presence/absence of an object for each pixel. In the present embodiment, calculator 140 outputs, to compositor 160, the subframe number and the determination result including “Z” indicating the presence of the object and “0” indicating the absence of the object.

Compositor 160 serves as a processor that generates a single distance image, based on the subframe number and the information regarding the presence/absence of an object obtained from calculator 140 for each of the plural subframes. Compositor 160 converts the subframe number outputted from calculator 140 to distance information, and then composes object-presence/absence information indicating the presence/absence of an object for each subframe, i.e., for each distance, thereby generating a single distance image. In other words, compositor 160 can generate a single distance image by composing a plurality of distance images (it may be referred to as “a distance image group”). For convenience of the description, the distance image for each of the distance measurement segments is also referred to as “a segment distance image”.

Compositor 160 generates a first distance image corresponding to the first frame based on the determination result regarding the object-presence/absence and the distance information for each of pixels 122a in the respective subframes in group A in the first frame (a distance image group in group A, e.g., a first distance image group described later), for example. Specifically, compositor 160 extracts and composites the determination result and the distance information for a subframe image (the segment distance image) in each of the subframes in group A, thereby generating a single first distance image.

Compositor 160 generates a second distance image corresponding to the second frame based on the determination result regarding the object-presence/absence and the distance information for each of pixels 122a in the respective subframes in group B in the second frame (a distance image group in group B, e.g., a second distance image group described later), for example. Specifically, compositor 160 extracts and composites the determination result and the distance information for a subframe image (the segment distance image) in each of the subframes in group B, thereby generating a single second distance image.

The first distance image and the second distance image may be obtained by performing distance measurement on the respective distance ranges different from each other, for example. The first distance image and the second distance image enable the distance to an object to be obtained in the entire distance range in which distance detection device 100 can measure a distance.

Compositor 160 may generate a three-dimensional distance image from the first distance image group. Compositor 160 may also generate a three-dimensional distance image from the second distance image group. Compositor 160 may preferentially select the determination result of a segment distance image at the near side in the depth direction, if calculator 140 determines that an object exists in a plurality of (two or more) segment distance images in one pixel 122a in the respective first distance image group and second distance image group.

Storage 150 is, for example, a random access memory (RAM), and stores data and others (e.g., LUT) to be used for calculation in calculator 140.

Outputter 170 adds distance information to a distance image prepared by composing, in compositor 160, the first distance image and the second distance image, and outputs the obtained distance image. Outputter 170 may add a color to the first distance image (e.g., a distance image generated through a first distance image group capturing step described later). The colors are individually set in the first distance image and are different from one another. Outputter 170 may provide the color to a three-dimensional distance image, for example. Outputter 170 may provide a color to pixel 122a, regarding which calculator 140 determines that an object exists, for example. Outputter 170 may also add a color to the second distance image. The colors are individually set in the second distance image (e.g., a distance image generated through a second distance image group capturing step described later) and are different from one another. The colors may be different from each other for the respective first distance image group and second distance image group.

Calculator 140 may determine that an object exists in a plurality of (two or more) segment distance images in one pixel 122a in each of the first distance image group and the second distance image group. In addition to such determination of calculator 140, compositor 160 may preferentially select the determination result of a segment distance image at the near side in the depth direction. In such a case, outputter 170 may add the color to the selected distance image among a plurality of distance images.

Outputter 170 may have an interface for outputting the distance image to the exterior of distance detection device 100. The interface includes a universal serial bus (USB) interface, for example. Outputter 170 outputs the distance image to an external personal computer (PC) and the like, for example. Although only an output operation from distance detection device 100 to the exterior is described here, a control signals or a program may be inputted to distance detection device 100 from an exterior PC and the like through the interface.

Controller 130, calculator 140, compositor 160, and outputter 170 are embodied by field programmable gate array (FPGA), for example. At least one of controller 130, calculator 140, and compositor 160 may be embodied by a reconfigurable processor that can reconfigure the connection and setting of circuit cells inside a large-scale integration (LSI), may be embodied by dedicated hardware (circuit), or may be embodied in a manner that a central processing unit (CPU), a processor, or such a program executor reads and executes a software program recorded in a hard disc, a semiconductor memory, or such a recording medium.

Configuration of camera 120 and various circuits in camera 120 are described with reference to FIGS. 3A to 3C. FIG. 3A is a circuit diagram showing a configuration of pixel 122a according to the present embodiment. FIG. 3A is a circuit diagram of one pixel 122a among a plurality of pixels included in image sensor 122.

As shown in FIG. 2, image sensor 122 includes three blocks including: light receiving circuit 123 that receives incident light; integration circuit 124: and output circuit 125. Hereinafter, specific configuration and function of each of the three blocks is described with reference to FIG. 3A. The specific configuration described hereinafter shows one example, so that the configuration of pixel 122a is not limited to the configuration described below. For example, other configurations having the similar functions as those in the present embodiment can exhibit the effects similar as those obtained in the present embodiment. It should be noted that, for various signals described below, “turned ON” means that a signal having a voltage value at a high level is applied, and “turned OFF” means that a signal having a voltage value at a low level is applied.

Each of a plurality of pixels 122a constituting image sensor 122 has light receiving circuit 123, integration circuit 124, and output circuit 125. A plurality of pixels 122a arranged in a two-dimensional manner form a pixel region (not shown).

As shown in FIG. 3A, light receiving circuit 123 has a function of outputting, to integration circuit 124, a light receiving signal that alters depending on the presence/absence of the incident light that arrives at the APD within a predetermined exposure time period. Light receiving circuit 123 has the APD, transistors TR1, and TR2.

The APD is an example of light receiving elements for detecting photons. Specifically, the APD is an avalanche multiplication photodiode. Thus, the APD is a photoelectric converter that photoelectrically converts incident light to generate electric charge, and multiplies the generated electric charge through an avalanche phenomenon. The APD has an anode connected to power source VSUB, and a cathode connected to floating diffusion FD via transistor TR2. The APD captures photons entering the APD, and generates electric charge from the captured photons. The generated electric charge is accumulated and held in floating diffusion FD via transistor TR2. Accordingly, the electric charge according to the generation frequency of the avalanche multiplication by the APD is accumulated in floating diffusion FD. Voltage supplied from power source VSUB is −20V, for example.

Transistor TR1 is a switching transistor connected between the APD and power source RSD. Transistor TR1 has a control terminal (e.g., a gate terminal) to which reset signal OVF serving as a control signal is inputted. Such reset signal OVF controls the conduction and non-conduction of transistor TR1. When reset signal OVF is turned ON, transistor TR1 is conducted, and a reset voltage is applied from power source RSD to the APD, to thereby reset the APD in an initial state. Here, the reset voltage is 3V, for example.

Transistor TR2 is a switching transistor connected between the APD and floating diffusion FD. Transistor TR2 has a control terminal (e.g., a gate terminal) to which read-out signal TRN serving as a control signal is inputted. Such read-out signal TRN controls the conduction and non-conduction of transistor TR2. When read-out signal TRN is turned ON, transistor TR2 is conducted, and electric charge generated in the APD is transferred to floating diffusion FD. Transistor TR2 can be referred to as a transfer transistor for transferring the electric charge generated in the APD to floating diffusion FD.

Controller 130 controls various control signals so that transistor TR1 is not conducted and transistor TR2 is conducted in accordance with exposure timing of the APD.

If exposure is performed multiple times in each of the subframes, integration circuit 124 can integrate (accumulate) electric charge generated by the multiple exposure. Integration circuit 124 converts the photon detected by the APD to a voltage, and integrates the voltage in each of the subframes in group A and each of the subframes in group B, for example. Then, integration circuit 124 outputs the integrated electric charge (it may also be referred to as a detection integration value) to output circuit 125. Integration circuit 124 has transistors TR3 and TR4, and electric-charge accumulation capacitor MIM1.

Transistor TR3 is a switching transistor (a counter transistor) connected between floating diffusion FD and electric-charge accumulation capacitor MIM1. Transistor TR3 has a control terminal (e.g., a gate terminal) to which integration signal CNT serving as a control signal is inputted. Such integration signal CNT controls the conduction and non-conduction of transistor TR3. When integration signal CNT is turned ON, transistor TR3 is conducted, and the electric charge accumulated in floating diffusion FD is accumulated in electric-charge accumulation capacitor MIM1. Accordingly, the electric charge according to the frequency of receiving of photons by the APD due to the exposure performed in multiple times is accumulated in electric-charge accumulation capacitor MIM1.

Transistor TR4 is a switching transistor connected between electric charge accumulation capacitor MIM1 and power source RSD. Transistor TR4 has a control terminal (e.g., a gate terminal) to which reset signal RST serving as a control signal is inputted. Such reset signal RST controls the conduction and non-conduction of transistor TR4. When reset signal RST is turned ON, transistor TR4 is conducted, and the reset voltage from power source RSD is applied to floating diffusion FD, to thereby reset the electric charge accumulated in floating diffusion FD into the initial state.

If transistors TR3 and TR4 are conducted, a reset voltage from power source RSD is applied to electric-charge accumulation capacitor MIM1, to thereby reset a voltage of electric charge accumulation capacitor MIM1 into a reset voltage (reset to the initial state).

Electric charge accumulation capacitor MIM1 is connected between an output terminal of light receiving circuit 123 and negative power source VSSA and accumulates electric charge generated in each exposure conducted in multiple times in a subframe. Electric charge accumulation capacitor MIM1 stores, as pixel voltages, a pixel signal corresponding to the number of the photon detected by pixel 122a, in the obtainment of a plurality of distance images groups including the first distance image group and the second distance image group. Accordingly, the electric charge is accumulated in electric-charge accumulation capacitor MIM1 every time the APD receives the photon. The voltage of electric-charge accumulation capacitor MIM1 in the initial state is 3V that is a reset voltage. When electric charge is accumulated in electric-charge accumulation capacitor MIM1, the voltage of electric-charge accumulation capacitor MIM1 is lowered from the voltage in the initial state. Electric-charge accumulation capacitor MIM1 is an example of a storage element provided in a circuit of pixel 122a.

Output circuit 125 amplifies voltage corresponding to the electric charge (detection integration value) accumulated in electric-charge accumulation capacitor MIM1, and outputs the amplified voltage to signal line SL. Output circuit 125 outputs a detection-integration value output signal in accordance with the detection integration value integrated by integration circuit 124 in each of the subframes in group A and each of the subframes in group B, for example. Output circuit 125 has transistor TR5 and transistor TR6. Here, the detection integration value is an example of the integrated value.

Transistor TR5 is an amplification transistor connected between transistor TR6 and power source VDD. Transistor TR5 has a control terminal (e.g., a gate terminal) connected to electric-charge accumulation capacitor MIM1, and a drain to which a voltage is supplied from power source VDD. Transistor TR5 outputs a detection-integration value output signal according to the quantity of the electric charge accumulated in electric-charge accumulation capacitor MIM1.

Transistor TR6 is a switching transistor (a selection transistor) connected between transistor TR5 and signal line SL (e.g., a row signal line). Transistor TR6 has a control terminal (e.g., a gate terminal) to which line-selection signal SEL serving as a control signal is inputted. Such a line-selection signal SEL controls the conduction and non-conduction of transistor TR6. Transistor TR6 determines timing of outputting the detection-integration value output signal. When line selection signal SEL is turned ON, transistor TR6 is conducted, and the detection-integration value output signal is outputted from transistor TR5 to signal line SL.

With reference to FIG. 2 again, CDS circuit 126 removes an offset component contained in the detection-integration value outputted signal outputted from pixel 122a. The offset component is an offset voltage signal that is superimposed on the detection-integration value output signal and is specific to transistor TR5. Such offset components may have different values depending on each pixel 122a.

CDS circuit 126 is described with reference to FIG. 3B. FIG. 3B is a circuit diagram showing a configuration of CDS circuit 126 according to the present embodiment. CDS circuit 126 is provided in each pixel row. In the correlated double sampling, a difference between the detection-integration value output signal supplied from a pixel and an output voltage from the amplification transistor after the voltage of electric-charge accumulation capacitor MIM1 is reset is subjected to sampling as an actual signal component. The correlated double sampling is not particularly limited, and a conventional technique may be used. Thus, detailed description regarding the correlated double sampling is omitted.

As shown in FIG. 3B, CDS circuit 126 includes inverter AMP1, first CDS circuit CDS1 (first correlated double sampling circuit), second CDS circuit CDS2 (second correlated double sampling circuit), and outputter AMP2. First CDS circuit CDS1 and second CDS circuit CDS2 are connected in parallel.

Inverter AMP1 performs inversion amplification on the detection-integration value output signal from signal line SL.

First CDS circuit CDS 1 includes transistors TR7 and TR8, and capacitor C1. Capacitor C1 has one end connected to negative power source VSSA. Transistor TR7 is a switching transistor connected between inverter AMP1 and the other end of capacitor C1. Transistor TR7 has a control terminal (e.g., a gate terminal) to which control signal ODD_SH is inputted. Such control signal ODD_SH controls the conduction and non-conduction of transistor TR7. When control signal ODD_SH is turned ON, transistor TR7 is conducted, and an offset-removed detection integration signal (a pixel signal) proportional to the difference between the detection-integration value output signal and the offset voltage signal is accumulated in capacitor C1.

Transistor TR8 is a switching transistor connected between outputter AMP2 and the other end of capacitor C1. Transistor TR8 has a control terminal (e.g., a gate terminal) to which control signal EVEN_SH is inputted. Such control signal EVEN_SH controls the conduction and non-conduction of transistor TR8. When control signal EVEN_SH is turned ON, transistor TR8 is conducted, and the offset-removed detection integration signal accumulated in capacitor C1 is outputted to outputter AMP2 (output buffer).

First CDS circuit CDS1 accumulates the offset-removed detection integration signal corresponding to one of pixels 122a adjacent to each other in a pixel line. First CDS circuit CDS1 accumulates offset-removed detection integration signals corresponding to pixels 122a in the odd-numbered lines, for example.

Second CDS circuit CDS2 includes transistors TR9 and TR10, and capacitor C2. Capacitor C2 has one end connected to negative power source VSSA. Transistor TR8 is a switching transistor connected between inverter AMP1 and the other end of capacitor C2. Transistor TR9 has a control terminal (e.g., a gate terminal) to which control signal EVEN_SH is inputted. Such control signal EVEN_SH controls the conduction and non-conduction of transistor TR9. When control signal EVEN_SH is turned ON, transistor TR9 is conducted, and an offset-removed detection integration signal (a pixel signal) proportional to the difference between the detection-integration value output signal and the offset voltage signal is accumulated in capacitor C2. In capacitor C2, an offset-removed detection integration signal of pixel 122a in a different pixel row from those in capacitor C1 is accumulated.

Transistor TR10 is a switching transistor connected between outputter AMP2 and the other end of capacitor C2. Transistor TR10 has a control terminal (e.g., a gate terminal) to which control signal ODD_SH is inputted. Such control signal ODD_SH controls the conduction and non-conduction of transistor TR10. When control signal ODD_SH is turned ON, transistor TR10 is conducted, and electric charge accumulated in capacitor C2 is outputted to outputter AMP2.

Second CDS circuit CDS2 accumulates the offset-removed detection integration signals corresponding to the other one of pixels 122a adjacent to each other in a pixel line. Second CDS circuit CDS2 accumulates offset-removed detection integration signals corresponding to pixels 122a in the even-numbered lines, for example.

As mentioned above, in CDS circuit 126, transistors TR7 and TR10 are simultaneously conducted, as well as transistors TR8 and TR9 are simultaneously conducted. Timing at which transistors TR7 and TR10 are conducted and timing at which transistors TR 8 and TR9 are conducted are controlled to be different from each other.

The offset-removed detection integration signal may be accumulated in capacitor C2, for example. In such a case, the conduction between transistor TR7 and transistor TR10 causes the offset-removed detection integration signal that has undergone the correlated double sampling processing to be accumulated in capacitor C1, and also causes the offset-removed detection integration signal accumulated in capacitor C2 to be outputted to ADC circuit 127. During outputting the offset-removed detection integration signals accumulated in capacitor C2 to ADC circuit 127 (e.g., during analog-to-digital (AD) conversion of the offset-removed detection integration signal), an offset-removed detection integration signal corresponding to pixel 122a that is different from pixel 122a corresponding to the offset-removed detection integration signal accumulated in capacitor C2 can be accumulated in capacitor C1. As mentioned above, transistors TR7 and TR10 as well as transistors TR8 and TR9 are alternately conducted, to thereby output the offset-removed detection integration signal accumulated in one of capacitors C1 and C2, and to accumulate the offset-removed detection integration signal in the other one of capacitors C1 and C2.

In the correlated double sampling, a difference between the detection-integration value output signal supplied from pixel 122a and an output voltage from the amplification transistor (e.g., transistor TR5) after the voltage of electric-charge accumulation capacitor MIM1 is reset is subjected to sampling as an actual signal component. The correlated double sampling is not particularly limited, and a conventional technique may be used. Thus, detailed description regarding the correlated double sampling is omitted.

As mentioned above, the offset removal operation and the AD conversion operation can be simultaneously performed in CDS circuit 126, so that the frame rate in image sensor 122 can be increased, in terms of hardware.

Hereinafter, ADC circuit 127 is described with reference to FIG. 3C. FIG. 3C is a circuit diagram showing a configuration of ADC circuit 127 according to the present embodiment.

As shown in FIG. 3C, ADC circuit 127 is provided in each pixel row. Conversion in the ADC is performed through a single-slope system, for example. A digital-to-analog converter (DAC) outputs a RAMP signal, and COMPARATOR compares the outputted RAMP signal with output signal CDSOUT from CDS circuit 126. At the moment when both signals are coincident, an output of COMPARATOR is inverted from an initial value, and a signal for stopping a counting operation in COUNTER in a later stage is outputted. A count value of COUNTER and the RAMP signal from the DAC synchronize with each other, and the stopped count value is proportional to output signal CDSOUT from CDS circuit 126. Thus, the count value is set as a digital value of output signal CDSOUT. Thereafter, the digital value is transferred to DATA-LATCH in each row, and then subjected to high speed transfer in DIGITAL-SHIFTREGISTER to be outputted from image sensor 122. In other words, ADC circuit 127 performs the high-speed transfer on the digitally-converted detection integration signal shown in FIG. 2, and subsequently outputs the signal to calculator 140 shown in FIG. 1.

### [1-2. Operation]

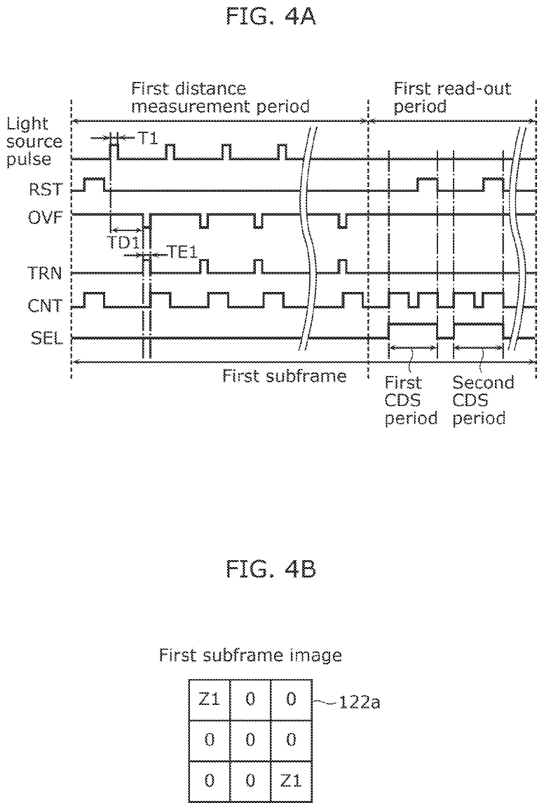

Description is given to an operation of generating a distance image in distance detection device 100 in which pixels 122a each having the aforementioned APD are arranged in a two-dimensional manner. First, schematic operations of generating a distance image in distance detection device 100 is described, with reference to FIGS. 4A to 7. FIG. 4A shows an example of the timings of distance measurement processing in the first subframe in group A of distance detection device 100 according to the present embodiment.

As mentioned above, controller 130 determines distance measurement ranges in the respective first and second frames that are different from each other, in a manner that a distance measurement range in the first frame and a distance measurement range in the second frame are different from each other. Controller 130 divides the first frame into a plurality of subframes, and sets the respective subframes to have distance measurement ranges different from one another and have no continuity in terms of distance, for example. Group A includes a plurality of subframes prepared by dividing the first frame. With reference to FIGS. 4A to 7, a case when the first frame is divided into three subframes (the first subframe, the third subframe, and the fifth subframe) is described. The first subframe, the third subframe, and the fifth subframe respectively have the distance measurement ranges of 9 m to 12 m, 15 m to 18 m, and 21 m to 24 m, for example. As mentioned above, the subframes are determined so that their distance measurement ranges have no distance continuity from one another. Distance measurement in each of the distance measurement ranges of 12 m to 15 m and 18 to 21 m is performed in the second frame, for example. In this case, the width of the distance measurement range (width of a distance measurement segment) is uniformly 3 m in the described examples. However, the width is not limited thereto.

As shown in FIG. 4A, the first subframe has a first distance measurement period and a first read-out period. In the first distance-measurement period, distance measurement is performed in the distance measurement range set for the first subframe. In the first read-out period, the detection-integration value output signal is read out (outputted) from pixel 122a to CDS circuit 126.

First, controller 130 applies reset signal RST to the gate terminal of transistor TR4 in integration circuit 124 to allow transistor TR4 to be conducted, and to allow electric-charge accumulation capacitor MIM1 to be reset.

Furthermore, controller 130 causes light source 110 to emit a light source pulse (light pulse) having a width corresponding to period T1. Although period T1 is, for example, 20 ns, it is not limited thereto.

If an object exists in a distance measurement range (9 m to 12 m in this case) subjected to the distance measurement within the first distance measurement range, reflection light reflected on the object arrives at distance detection device 100 behind, by period TD1, the time point at which the light source pulse is emitted from light source 110. In view of the above, if the exposure is set to start at this time point and to be performed only during period TE1 by read-out signal TRN from light receiving circuit 123, the reflection light from the object existing in this distance measurement range can be detected. Period TD1 is determined based on the minimum value of the distance measurement range (9 m in this case) and the velocity of light. Period TE1 is determined based on the difference between the minimum value and the maximum value of the distance measurement range (12 m in this case) and the velocity of light. Period TD1 is 60 ns, and period TE1 is 20 ns, for example.

In FIG. 4A, period TE1 corresponds to the exposure period. In period TE1, transistor TR1 is not conducted and transistor TR2 is conducted. After the exposure period, transistor TR1 is conducted and transistor TR2 is not conducted. With these operations, the APD is reset.

Thereafter, integration signal CNT causes transistor TR3 to be conducted in integration circuit 124. Accordingly, the electric charge accumulated in floating diffusion FD is accumulated in electric-charge accumulation capacitor MIM1.

In the first distance measurement period, the above operations are repeatedly performed at the predetermined number of times. Here, the predetermined number of times is not limited. In the first distance measurement period, it is satisfied that the above operations are performed at least once. If the above operations are repeatedly performed at the predetermined times in the first distance measurement period, the electric charge accumulated in electric-charge accumulation capacitor MIM1 increases every time the APD receives the reflection light.

After the first distance measurement period elapses, processing is shifted to the first read-out period, and the detection-integration value output signal corresponding to the electric charge accumulated in electric-charge accumulation capacitor MIM1 is outputted from output circuit 125 to CDS circuit 126. A first CDS period is a period for outputting the detection-integration value output signal from output circuit 125 to CDS circuit 126. In the first CDS period, transistor TR3 is first conducted among transistors TR3 and TR4. Accordingly, the detection-integration value output signal is outputted from output circuit 125 to CDS circuit 126. Thereafter, during the first CDS period, both transistors TR3 and TR4 are conducted. With these operations, electric-charge accumulation capacitor MIM1 is reset. Transistors TR3 and TR4 are again in the non-conducted state, so that the reset operation of electric-charge accumulation capacitor MIM1 is completed.

A second CDS period is a period for outputting a reset voltage signal corresponding to the voltage at which electric-charge accumulation capacitor MIM1 is in the initial state, from output circuit 125 to CDS circuit 126. In the second CDS period, transistor TR3 is first conducted among transistors TR3 and TR4. Accordingly, the reset voltage signal is outputted from output circuit 125 to CDS circuit 126. Thereafter, during the second CDS period, both transistors TR3 and TR4 are conducted. With these operations, electric-charge accumulation capacitor MIM1 is again reset. Transistors TR3 and TR4 are again in the non-conducted state, so that the reset operation of electric-charge accumulation capacitor MIM1 is completed.

With these operations, an offset-removed detection integration signal based on the difference between the detection-integration value output signal and the reset voltage signal is generated and accumulated in CDS circuit 126. The offset-removed detection integration signal depends only on the intensity of the reflection light received by the APD.

Then, the offset-removed detection integration signal is converted to digital signals in ADC circuit 127, and calculator 140 performs determination regarding presence/absence of an object, and other processing. Then, the determination result is outputted to compositor 160.

As mentioned above, distance detection device 100 according to the present embodiment performs, immediately after the distance measurement, read-out processing of reading out the detection-integration value output signal generated through the distance measurement. Accordingly, pixel 122a (image circuit) can be simply configured, so that pixel 122a (image circuit) can be miniaturized.

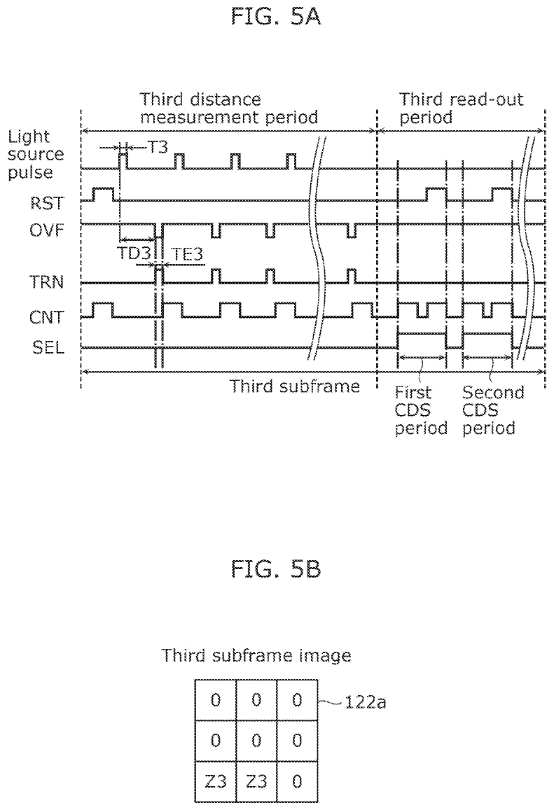

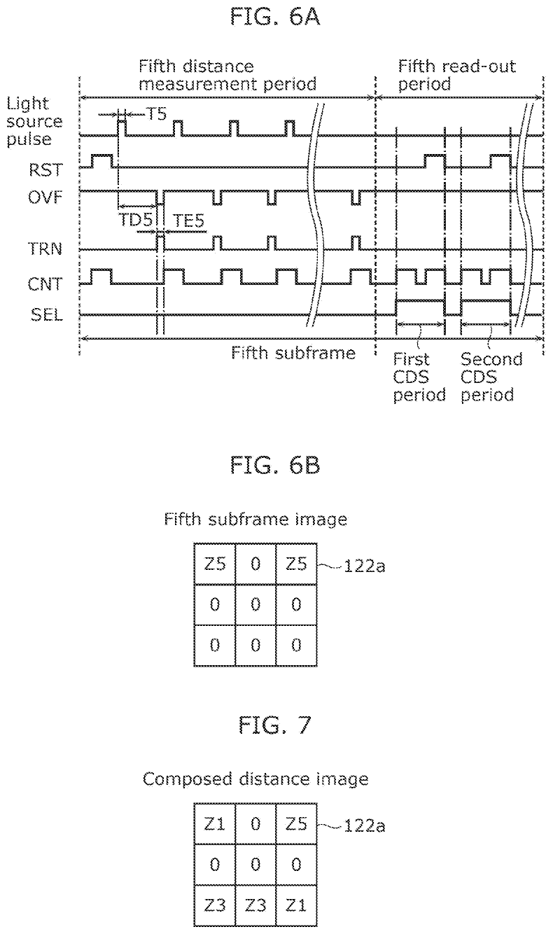

FIG. 4B is a diagram showing a first subframe image according to the present embodiment. FIG. 4B also shows an image formed by three pixels in the respective vertical and horizontal directions. It should be noted that the same should be applied to FIGS. 5B and 6B described later.

FIG. 4B shows a case where calculator 140 determines that an object exists in two of nine pixels, based on digital signals and the LUT. In FIG. 4B, “Z1” denotes information indicating the determination that the object is present in the first subframe. Pixel 122a allocated with “Z1” in FIG. 4B is determined to have an object in the first subframe. “Z1” has distance information.

Hereinafter, the third subframe is described with reference to FIGS. 5A and 5B. The third subframe is, for example, subjected to the distance measurement later relative to the first subframe. In the third subframe, the distance measurement is performed in a range in a longer distance than that in the first subframe. FIG. 5A shows an example of the timings of distance measurement processing in the third subframe in distance detection device 100 according to the present embodiment.

As shown in FIG. 5A, the third subframe has a third distance measurement period and a third read-out period. In the third distance-measurement period, distance measurement is performed. In the third read-out period, the detection-integration value output signal is read out (outputted) from pixel 122a to CDS circuit 126.

In the third distance measurement period, period TD3 from the emission of a light source pulse to the start of exposure is different from period TD1 in the first distance measurement period. In the third subframe, the distance measurement is performed in a range with a longer distance than that in the first subframe. Thus, period TD3 is longer than period TD1. Accordingly, timings of supplying read-out signals TRN in response to the emission of light source pulses are different among the respective subframes, depending on the distance measurement ranges in the respective subframes. Period T3 may be the same as period T1, and is 20 ns, for example. The difference between the maximum value and the minimum value (3 m in this case) in the distance measurement range is the same as that in the first subframe, so that period TE3 is the same as period TE1, and is 20 ns, for example.

Processing performed in the third read-out period is the same as that performed in the first read-out period, so that the detailed description of such processing is omitted.

FIG. 5B is a diagram showing a third subframe image according to the present embodiment.

FIG. 5B shows a case where calculator 140 determines that an object is present in two of nine pixels. Pixel 122a allocated with “Z3” in FIG. 5B is determined to have an object in the third subframe.

Hereinafter, the fifth subframe is described with reference to FIGS. 6A and 6B. The fifth subframe is, for example, subjected to the distance measurement later relative to the third subframe. In the fifth subframe, the distance measurement is performed in a range in a longer distance than that in the third subframe. FIG. 6A shows an example of the timings of distance measurement processing in the fifth subframe in distance detection device 100 according to the present embodiment.

As shown in FIG. 6A, the fifth subframe has a fifth distance measurement period and a fifth read-out period. In the fifth distance-measurement period, distance measurement is performed. In the fifth read-out period, the detection-integration value output signal is read out (outputted) from pixel 122a to CDS circuit 126.

In the fifth distance measurement period, period TD5 from the emission of a light source pulse to the start of exposure is different from period TD3 in the third distance measurement period. In the fifth subframe, the distance measurement is performed in a range in a longer distance than that in the third subframe. Thus, period TD5 is longer than period TD3. Period T5 may be the same as period T3, and is 20 ns, for example. The difference between the maximum value and the minimum value in the distance measurement range (3 m in this case) is the same as that in the third subframe, so that period TE5 is the same as period TE3, and is 20 ns, for example.

Processing performed in the fifth read-out period is the same as that performed in the third read-out period, so that the detailed description of such processing is omitted.

FIG. 6B is a diagram showing a fifth subframe image according to the present embodiment.

FIG. 6B shows a case where calculator 140 determines that an object is present in two of nine pixels. Pixel 122a indicated by “Z5” in FIG. 6B is a pixel determined to have an object in the fifth subframe.

Next, generation of distance image in compositor 160 is described, with reference to FIG. 7. FIG. 7 is a diagram showing a distance image after composition, according to the present embodiment.

As shown in FIG. 7, compositor 160 generates a distance image (an example of the first distance image) in the first frame, based on the first subframe image, the third subframe image, and the fifth subframe image. Compositor 160 composes the first subframe image, the third subframe image, and the fifth subframe image, so as to generate a single distance image in the first frame.

The first subframe image is, among the first, third, and fifth subframes, associated with the distance information “Z1” in lower right pixel 122a, for example. Accordingly, compositor 160 sets lower right pixel 122a as the distance information “Z1”, for example. In other words, compositor 160 associates such lower right pixel 122a with the information indicating that an object is presence in a position in a range from 9 m to 12 m, which is the distance measurement range for the first subframe in group A.

Calculator 140 may determine that an object is present in two or more subframes (two or more segment distance images) for a single pixel 122a. For example, calculator 140 determines that an object is present in each of the measurement distance ranges of 9 m to 12 m and 18 m to 21 m at upper left pixel 122a, as shown in FIGS. 4B and 6B. In such a case, compositor 160 appropriately select one of the ranges depending on use application of distance detection device 100. If distance detection device 100 is used for an automobile, for example, information regarding a short distance affects greater in driving than other information does. Accordingly, compositor 160 preferentially select the information of the short distance. In the present embodiment, compositor 160 selects “Z1” indicating that an object is present in a range from 9 m to 12 m, as shown in FIG. 7.

As mentioned above, when calculator 140 determines, for a single pixel 122a, that an object is present in two or more subframes among subframes in group A in the first frame, compositor 160 may generate the first distance image in accordance with the determination result of the subframe of group A, in which the distance measurement is performed in the distance measurement range of a shorter distance among the two or more subframes in group A. It should be noted that the same should be applied to the second frame.

Information of a long distance may be preferentially selected depending on the use application of distance detection device 100.

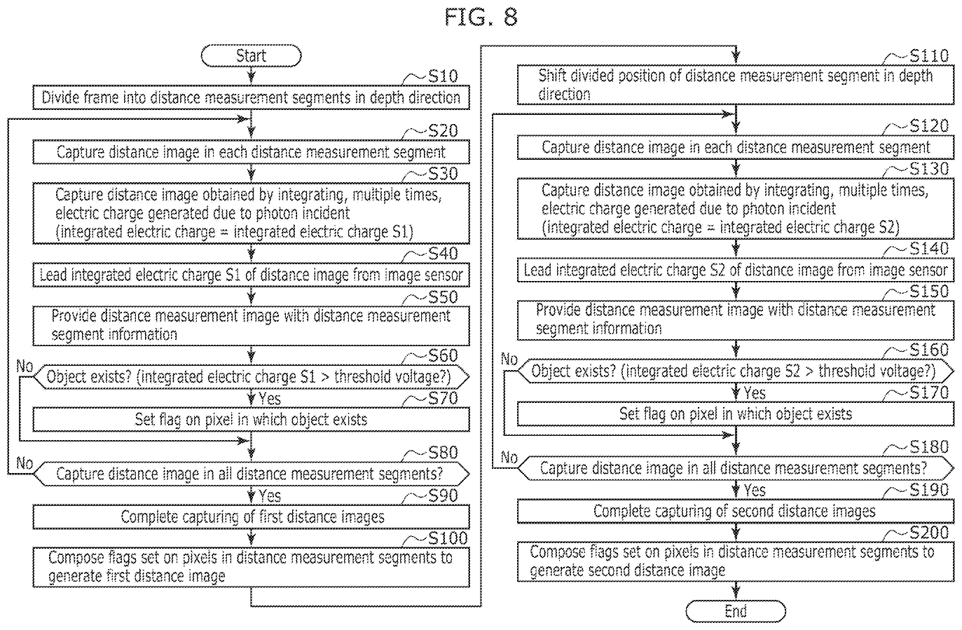

Here, operations of generating a distance image in distance detection device 100 are described. FIG. 8 is a flowchart showing an example of distance image generation processing in distance detection device 100 according to the present embodiment. Processing from Step10 to Step S100 described below is an example of a first distance detection step in which distance to an object is detected in the first frame. Processing from Step110 to Step S200 described below is an example of a second distance detection step in which distance to an object is detected in the second frame. Step S10 is an example of a setting step, Steps S20 to S90 are an example of a first distance image group capturing step, and steps S110 to S190 are an example of a second distance image group capturing step. The first distance image group capturing step and the second distance image group capturing step are included in an image capturing step.

As shown in FIG. 8, controller 130 divides distance to be measured along a depth direction (Step S10). The depth direction corresponds to an image capturing direction by image sensor 122, and includes the front, for example. Controller 130 divides the distance to be measured per a distance from image sensor 122, for example. If a range to be measured by image sensor 122 is 9 m to 15 m, for example, controller 130 sets the distance measurement range of 9 m to 12 m as one distance measurement segment and the distance measurement range of 12 m to 15 m to another distance measurement segment. This is an example of the segmentation of the distance to be measured in the depth direction. Controller 130 may set distance measurement segments so that the respective segments have the distance continuity in the depth direction. Specifically, controller 130 may set distance measurement ranges that are different from one another and have distance continuity, respectively to the distance measurement segments in group A. Controller 130 can also divide the first frame into a plurality of subframes each of which corresponds to a distance measurement segment. A part of subframes (a group of subframes) in the distance measurement segments is included in group A. The number of the division is not particularly limited. Each of the distance measurement segments is an example of a distance-divided segment.

Although an example in which the width of each distance measurement segment (width of the distance) is identical (e.g., 3 m) is described, the width is not limited thereto. Controller 130 may set a distance of the distance measurement segment in a front side (a side closer to camera 120) in the depth direction to be narrower than a distance of the distance measurement segment in a back side in the depth direction. Controller 130 may gradually vary the distance of the distance measurement segment from the front side to the back side in the depth direction. Controller 130 may gradually increase the distance of the distance measurement segment from a distance measurement segment in the front side to a distance measurement segment in the back side in the depth direction (e.g., with increase in distance from camera 120).

Controller 130 may set distance measurement segments in group A (e.g., the respective subframes) to have no continuity. Specifically, controller 130 may set distance measurement ranges that are different from one another and have no distance continuity to the distance measurement segments in group A, respectively. Step S10 is also an example of a first setting step.

Then, controller 130 captures a distance image for each distance measurement segment in group A (Step S20). Controller 130 causes light source 110 and camera 120 to measure the distance in each of the distance measurement segments in group A, which are set in Step S10. Controller 130 controls light source 110 and camera 120 in a manner described above with reference to FIG. 4A and so on, for example. The distance measurement segments in group A are a part of the distance measurement segments set in Step S10.

Image capturing in Step S20 is performed, to thereby capture a distance image obtained by integrating, multiple times, electric charge generated due to photon incident, in the distance measurement segment (Step S30). The integrated electric charge is also described as integrated electric charge S1. Capturing the distance image here corresponds, for example, to obtainment of integrated electric charge S1 of the distance image. Integrated electric charge S1 corresponds to the detection integration value shown in FIG. 2. In addition, integrated electric charge S1 is accumulated in electric-charge accumulation capacitor MIM1. Steps S20 and S30 are an example of a first distance measurement step.

Then, calculator 140 leads integrated electric charge S1 of the distance image from image sensor 122 (Step S40). Accordingly, a detection-integration value output signal corresponding to integrated electric charge S1 (a voltage signal corresponding to light received by the APD) is outputted, for each of the distance measurement segments in group A, to the exterior of pixel 122a.

Step S40 may include a CDS processing step and an output step. In the CDS processing step, the correlated double sampling processing is performed on a detection-integration value output signal outputted from pixel 122a, and the processed signal is held. In the output step, a detection-integration value output signal that has been obtained prior to the detection-integration value output signal processed in the CDS processing step (i.e., the detection-integration value output signal outputted from adjacent pixel 122a in a pixel row), has undergone the correlated double sampling processing, and is held (i.e., the offset-removed detection integration signal) is outputted. The CDS processing step and the output step are performed in parallel.

For example, the CDS processing step is performed in the first read-out period shown in FIG. 4A and so on, while in the first read-out period, the offset-removed detection integration signal that has undergone the correlated double sampling is outputted from CDS circuit 126 to ADC circuit 127. In other words, during the correlated double sampling processing for the detection-integration value output signal, the offset-removed detection integration signal that has undergone the correlated double sampling processing is outputted.

Then, calculator 140 provides the distance image with distance measurement segment information (Step S50). The distance measurement segment information contains information indicating a distance measurement segment, and contains information based on the number of a subframe, for example.

Then, calculator 140 determines the presence/absence of an object based on the result of the distance measurement (e.g., digital signals generated in accordance with the detection-integration value output signal) for each distance measurement segment in group A (Step S60). Calculator 140 compares integrated electric charge S1 (an example of a first voltage signal) with a threshold voltage. Calculator 140 compares a signal (voltage signal) corresponding to integrated electric charge S1 with the threshold voltage, for example. Then, calculator 140 sets a flag on a pixel determined to have an object (Step S70), if integrated electric charge S1 is greater than the threshold voltage (Yes in Step S60). The processing in Step S70 is performed for each pixel 122a. The flag is set on pixel 122a determined to have an object in the subframe. If integrated electric charge S1 is less than or equal to the threshold voltage (No in Step S60), calculator 140 allows the processing to advance to Step S80.

Calculator 140 outputs the determination result and the distance measurement segment information to compositor 160, for each distance measurement segment in group A. The determination result is, for example, a subframe image shown in FIG. 4B and so on. Step S60 is an example of a first determination step.

Then, controller 130 determines whether distance images in all distance measurement segments in group A are captured (Step S80). If controller 130 determines distance images in all distance measurement segments in group A are captured (Yes in Step S80), compositor 160 completes the capturing of the first distance image group (S90), and composes the flags set on pixels 122a in the respective distance measurement segments to generate and output the first distance image (Step S100). Step S100 is an example of a first distance image generation step.

Determining that distance images in all distance measurement segments in group A are not captured (No in Step S80), controller 130 returns the processing to Step S20 and continues the processing from Steps S20 to S70 until the capturing of the distance images in all distance measurement segments is completed.

Subsequently, processing of generating a second distance image in a second frame is performed. The second distance image is generated based on results of distance measurement performed in distance measurement segments that have not undergone the distance measurement regarding the first distance image.

Controller 130 causes a divided position (divided distance) of the distance measurement segment to be shifted in the depth direction from the distance measurement segment set in Step S10 (Step S110). Controller 130 can set a distance measurement segment in a phase different from that of the distance measurement segment set in Step S10. Controller 130 can also divide the second frame into a plurality of subframes each of which corresponds to a distance measurement segment. Subframes corresponding to the distance measurement segments (subframes) are included in group B. The number of division is not limited, but may be the same as the number of subframes in group A.

Controller 130 may set distance measurement segments that are not set in group A and do not continue to one another, as distance measurement segments in group B. Controller 130 may set distance measurement ranges, among those that are not set in the first frame, which are different from one another, and have no distance continuity, to the distance measurement segments in group B, respectively. Specifically, controller 130 may select, in view of a distance measurable range in distance detection device 100, distance measurement ranges that are not set in the first frame, and may respectively allocate the selected distance measurement ranges to distance measurement segments in group B, so as to set the distance measurement segments. Such allocation of the distance measurement segments is included in the processing of shifting the divided position of the distance measurement segment in the depth direction.

Then, controller 130 captures a distance image for each distance measurement segment in group B (Step S120). Controller 130 causes light source 110 and camera 120 to measure a distance in each of the distance measurement segments set in Step S110.

Image capturing in Step S120 is performed, to thereby capture a distance image obtained by integrating, multiple times, electric charge generated due to photon incident in the distance measurement segment (Step S130). The integrated electric charge is also described as integrated electric charge S2. Capturing the distance image here corresponds, for example, to obtainment of integrated electric charge S2 of the distance image. Integrated electric charge S2 corresponds to a detection integration value shown in FIG. 2. In addition, integrated electric charge S2 is accumulated in electric-charge accumulation capacitor MIM1. Steps S120 and S130 each are an example of a second distance measurement step.

Then, calculator 140 leads integrated electric charge S2 of the distance image from image sensor 122 (Step S140). Accordingly, a detection-integration value output signal corresponding to integrated electric charge S2 (a voltage signal corresponding to light received by the APD) is outputted, for each of the distance measurement segments in group B, to the exterior of pixel 122a.

Step S140 further includes a CDS processing step and an output step, as Step S40, and the CDS processing step and the output step may be performed in parallel.

Then, calculator 140 provides the distance image with distance measurement segment information (Step S150).

Then, calculator 140 determines the presence/absence of an object based on the result of the distance measurement (a digital signal) for each distance measurement segment in group B (Step S160). Calculator 140 compares integrated electric charge S2 with a threshold voltage. Then, calculator 140 sets a flag on a pixel determined as an object being present (Step S170), if integrated electric charge S2 is larger than the threshold voltage (Yes in Step S160). In the distance image, the flag is set on the pixel determined in which an object is present. If integrated electric charge S2 is less than or equal to the threshold voltage (No in Step S160), calculator 140 advances the processing to Step S180. Although the threshold voltage used in Step S160 and the threshold voltage used in Step S60 have the same voltage value, these voltages may have values different from each other.

Calculator 140 outputs the determination result and the distance measurement segment information to compositor 160, for each distance measurement segment in group B. Step S160 is an example of a second determination step.

Then, controller 130 determines whether distance images in all distance measurement segments in group B are captured (Step S180). If controller 130 determines that the distance images in all the distance measurement segments in group B are captured (Yes in Step S180), compositor 160 completes the capturing of the second distance image group (S190), and composes the flags set on pixels 122a in the respective distance measurement segments to generate and output the second distance image (Step S200). Step S200 is an example of a second distance image generation step.

Determining that the distance images in all the distance measurement segments in group B are not captured (No in Step S180), controller 130 returns the processing to Step S120 and continues processing from Steps S120 to S170 until the capturing of the distance images in all the distance measurement segments is completed.

Distance detection device 100 repeatedly performs the processing from Step S10 to Step S200 shown in FIG. 8. In other words, the first distance image and the second distance image are alternately generated. Specifically, controller 130 causes light source 110 and camera 120 to alternately generate the first distance image and the second distance image, for example. Accordingly, outputter 170 can output the first distance image and the second distance image, alternately.

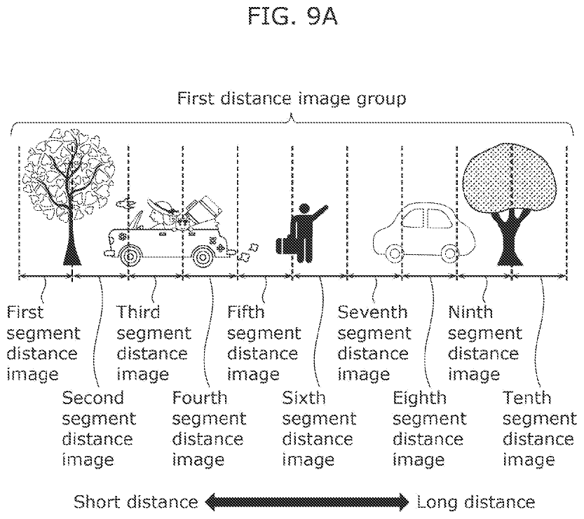

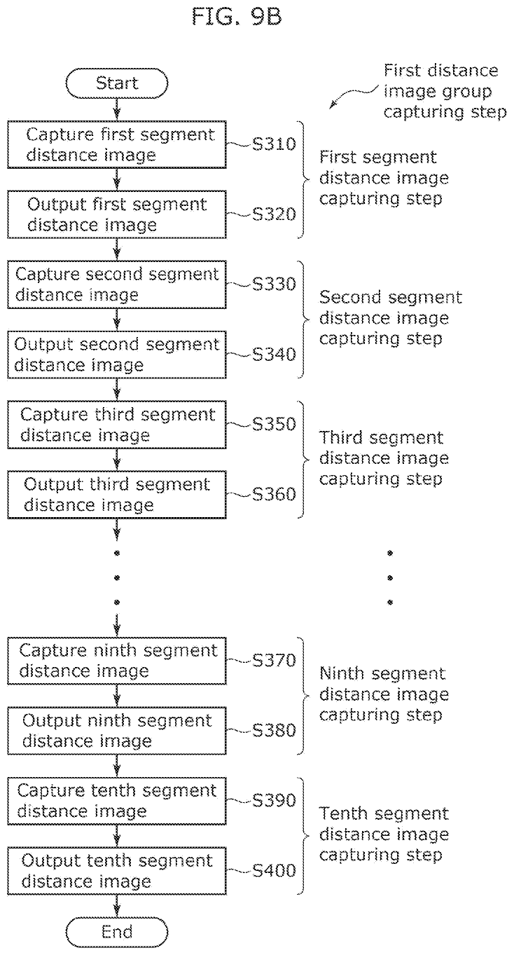

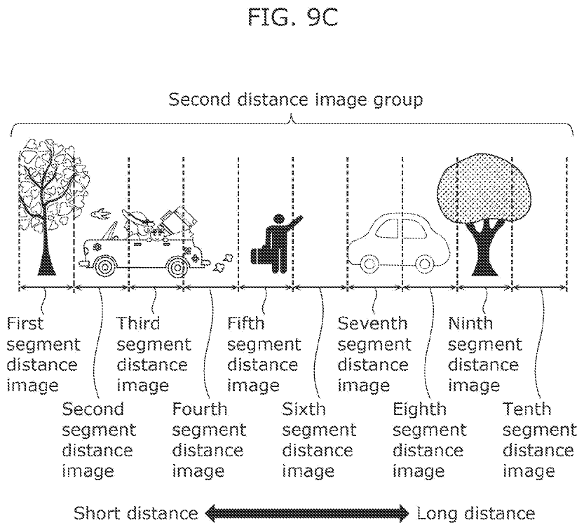

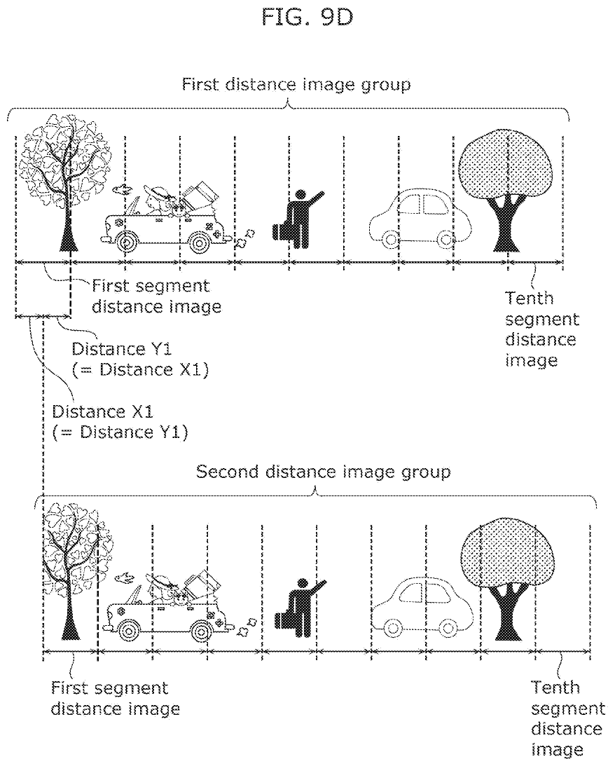

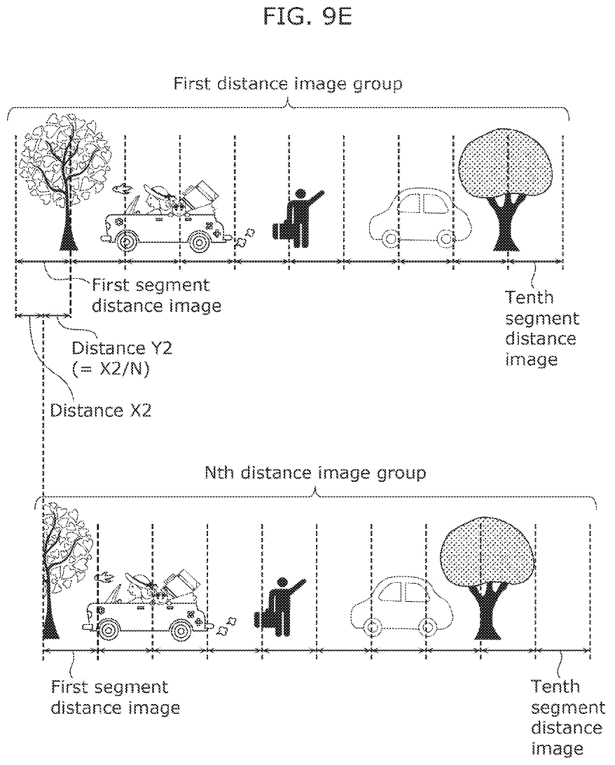

Hereinafter, the first distance image generated in Step S100 and the second distance image generated in Step S200 are described with reference to FIGS. 9A to 9E. FIG. 9A is a pattern diagram for describing an example of the first distance image according to the present embodiment. FIG. 9B is a flowchart typically showing flow of generating the first distance image according to the present embodiment. FIG. 9B shows a case where processing from Steps S20 to S80 shown in FIG. 8 is repeatedly performed. Specifically, FIG. 9B shows a case where processing from Steps S20 to S40 is repeatedly performed. The flowchart shown in FIG. 9B is an example of the first distance image group capturing step. FIG. 9C is a pattern diagram for describing an example of the second distance image according to the present embodiment. FIGS. 9A to 9E show a case in which the distance measurement segments in group A and the distance measurement segments in group B are set to be continuable to one another.

As shown in FIG. 9A, the first distance image group includes distance images from a first segment distance image to a tenth segment distance image. For example, a first distance measurement segment corresponding to the first segment distance image and a second distance measurement segment corresponding to the second segment distance image continue to each other. The width of each distance measurement segment in the first distance image group may be identical to each other. For example, the width may be 3 m and the like. FIG. 9A shows an example in which a distance measurement segment corresponding to the first segment distance image to a distance measurement segment corresponding to the tenth segment distance image, among distance measurement segments set in Step S10 are set as distance measurement segments in frame A (distance measurement segments for generating the first distance image).

As shown in FIG. 9B, image sensor 122 first captures the first segment distance image (Step S310), and then outputs the first distance image (Step S320). The first segment distance image shown in FIG. 9A is generated in Step S310 and Step S320 shown in FIG. 9B. Processing in Step S310 corresponds to processing in Step S20 and Step S30 in the first distance measurement segment, and processing in Step S320 corresponds to processing in Step S40 in the first distance measurement segment. Processing in Steps S310 and S320 each are an example of a first segment distance image capturing step. Processing in Steps S310 and S320 are performed in the first subframe shown in FIG. 4A, processing in Step S310 is performed in the first distance measurement period, and processing in Step S320 is performed in the first read-out period.

Image capturing and outputting of a second segment distance image to a tenth segment distance image (Steps S330 to S400) are sequentially performed similarly.

As shown in FIG. 9C, the second distance image group includes a first segment distance image to a tenth segment distance image. For example, a first distance measurement segment corresponding to the first segment distance image and a second distance measurement segment corresponding to the second segment distance image continue to each other. The width of each distance measurement segment in the second distance image group may be identical to each other. For example, the width may be 3 m and the like. In addition, at least a part of the first distance measurement segment in the second distance image group and at least a part of the first distance measurement segment in the first distance image group are different from each other.

Here, relationship between distance measurement segments in the respective distance image groups is described, with reference to FIGS. 9D and 9E. FIG. 9D is a diagram showing a first example of the relationship between distance measurement segments in the respective frames according to the present embodiment. Specifically, FIG. 9D shows an example of the relationship between distance measurement segments in the respective first distance image group and second distance image group.

As shown in FIG. 9D, at least a part of the first distance measurement segment in the first distance image group and at least a part of the first distance measurement segment in the second distance image group may overlap with each other. Distance from the minimum value of a distance measurement range of the first distance measurement segment in the first distance image group to the minimum value of a distance measurement range of the first distance measurement segment in the second distance image group is set as “distance x1”. Distance from the minimum value of the distance measurement range of the first distance measurement segment in the second distance image group to the maximum value of the distance measurement range of the first distance measurement segment in the first distance image group is set as “distance Y1”. In this circumstance, distance x1=distance Y1 may be established, for example. In other words, a half of the first distance measurement segment in the first distance image group may be overlapped with the first distance measurement segment in the second distance image group.

For example, if a difference between the maximum value and the minimum value of each distance measurement segment in the first distance image group and such a difference in each distance measurement segment in the second distance image group (i.e., the width of each distance measurement segment) are identical to each other, the first distance measurement segment in the second distance image group overlaps with a half of the first distance measurement segment and a half of the second distance measurement segment in the first distance image group. In other words, a plurality of distance measurement segments contained in the first distance image group capturing step and a plurality of distance measurement segments contained in the second distance image group capturing step may be displaced from each other by a half segment. In this case, the width of each distance measurement segment in the first distance image group and the width of each distance measurement segment in the second distance image group may be identical, for example.

FIG. 9E is a diagram showing a second example of the relationship between distance measurement segments in the respective frames according to the present embodiment. Specifically, FIG. 9E shows an example of the relationship between distance measurement segments in the first distance image group and the Nth distance image group. Here, N is an integer more than or equal to 3.

As shown in FIG. 9E, at least a part of the first distance measurement segment in the first distance image group and at least a part of a first distance measurement segment in the Nth distance image group may overlap with each other. Distance from the minimum value of the distance measurement range of the first distance measurement segment in the first distance image group to the minimum value of the distance measurement range of the first distance measurement segment in the Nth distance image group is set as “distance X2”. Distance from the minimum value of the distance measurement range of the first distance measurement segment in the Nth distance image group to the maximum value of the distance measurement range of the first distance measurement segment in the first distance image group is set as “distance Y2”. In this circumstance, distance Y2=distance X2/N may be established, for example. In other words, a plurality of distance measurement segments contained in the first distance image group capturing step and a plurality of distance measurement segments contained in the Nth distance image group capturing step may be displaced from each other by a half segment. Thus, the distance measurement segments from the first distance image group to the Nth distance image group may be displaced at an equal interval.

As mentioned above, the distance measurement segments in the first distance image group and those in the second distance image group are set so that at least a part of each of the distance measurement segments in the respective groups overlaps with each other. Accordingly, even if distance measurement is not accurately performed in a segment in one of the first distance image group and the second distance image group, distance measurement performed in the other distance image group compensates the inaccurate distance measurement. Thus, measurement accuracy is improved. In addition, the distance measurement range is changed in the respective distance image group, thereby enabling the distance measurement in a broad range from a short distance to a long distance without decreasing the resolution.

A part of the first distance measurement segment in the second distance image group may overlap with any one of the distance measurement segments in the first distance image group.

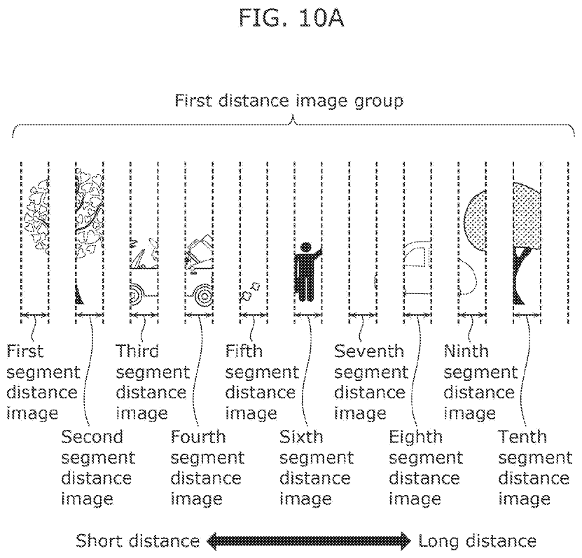

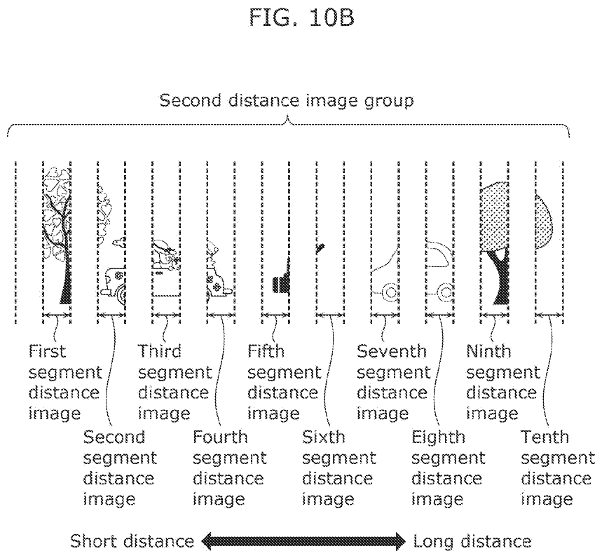

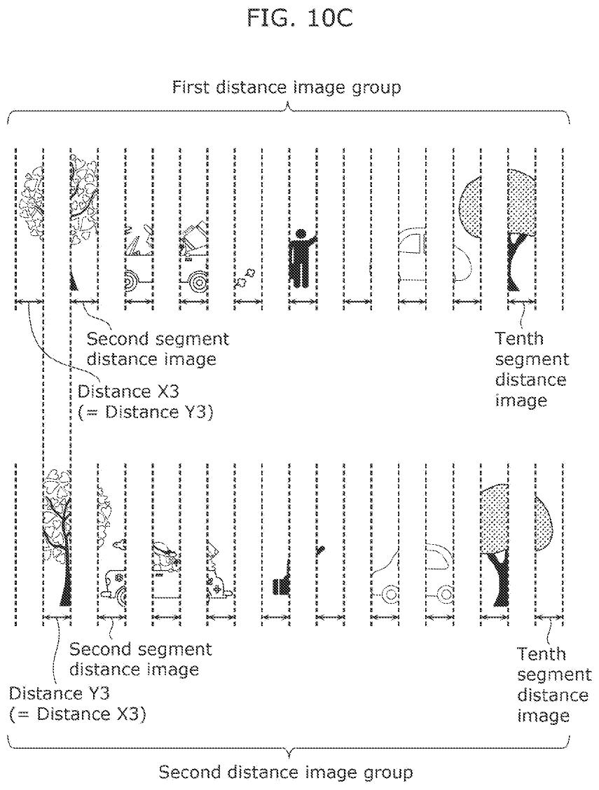

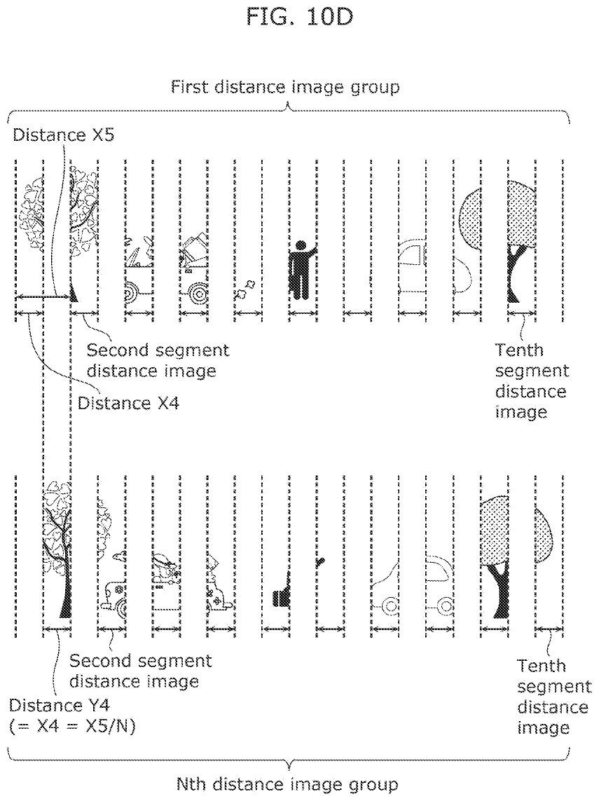

Hereinafter, setting of a distance measurement segment in each of the distance image groups is described, with reference to FIGS. 10A to 10D. FIG. 10A is a pattern diagram for describing another example of the first distance image according to the present embodiment. FIG. 10B is a pattern diagram for describing another example of the second distance image according to the present embodiment. FIGS. 10A to 10D show a case in which the distance measurement segments in each of group A and group B are set as non-continuous distance measurement segments.

As shown in FIG. 10A, the first distance image group includes a first segment distance image to a tenth segment distance image. For example, the first distance measurement segment corresponding to the first segment distance image and a second distance measurement segment corresponding to the second segment distance image are the non-continuous distance measurement segments. The width of each distance measurement segment in the first distance image group may be identical. For example, the width may be 3 m and the like.

As shown in FIG. 10B, the second distance image group includes a first segment distance image to a tenth segment distance image. For example, a first distance measurement segment corresponding to the first segment distance image and a second distance measurement segment corresponding to the second segment distance image are non-continuous distance measurement segments. The width of each distance measurement segment in the second distance image group may be identical. For example, the width may be 3 m and the like. In addition, at least a part of the first distance measurement segment in the second distance image group and at least a part of the first distance measurement segment in the first distance image group are different from each other. In other words, at least a part of the first distance measurement segment in the second distance image group and at least a part of the first distance measurement segment in the first distance image group may overlap with the other.

Here, setting of the distance measurement segments in each of the distance image group is described, with reference to FIGS. 10C and 10D. FIG. 10C is a diagram showing a second example of the relationship between the distance measurement segments in the respective frames according to the present embodiment. Specifically, FIG. 10C shows an example of the relationship between distance measurement segments in each of the first distance image group and the second distance image group.

Distance detection device 100 can measure a distance from 9 m to 69 m, and it is assumed that a distance measurement range in each distance measurement segment is set in a range of every 9 to 3 m. Thus, the width of the distance measurement segment is set to 3 m. Specifically, a distance measurement range of the first distance measurement segment (the first subframe) in the first distance image group (group A) is 9 m to 12 m, a distance measurement range of the first distance measurement segment (the second subframe) in the second distance image group (group B) is 12 m to 15 m, a distance measurement range of the second distance measurement segment (the third subframe) in the first distance image group is 15 m to 18 m, . . . , and a distance measurement range of the tenth distance measurement segment in the second distance image group (distance measurement range of the tenth subframe) may be 66 m to 69 m, for example. The distance ranges are set intermittently both in the first distance image group and in the second distance image group.

As shown in FIG. 10C, the first distance image group and the second distance image group compensate a missing distance measurement range, with each other. In other words, controller 130 sets the distance measurement range of each distance measurement segment in the first distance image group and the second distance image group so that these groups compensate the missing distance measurement range together with each other. Controller 130 causes light source 110 and camera 120 to alternately generate images of the first distance image group and images of the second distance image group, thereby allowing distance detection device 100 to secure the distance continuity in the distance measurement ranges for each of the frames.

Here, a period of each distance measurement segment may be 4.3 msec (e.g., the distance measurement period is 1 msec and the read-out period is 3.3 msec), for example. In the present embodiment, each of the first distance image group and the second distance image group is composed of ten distance measurement segments (segment distance images), and thus a frame velocity of a single frame is 43 msec (the frame rate is 23.3 fps). Meanwhile, if all of 20 distance measurement segments in a single frame are subjected to the distance measurement as a comparative example, the frame velocity of a single frame is 86 msec (the frame rate is 11.6 fps). Therefore, an apparent frame rate can be improved according to the present embodiment.

Although the description is given to an example in which the distance measurement ranges set in the first frame and those set in the second frame do not overlap with each other, the present disclosure is not limited thereto. For example, a part of a distance measurement range set in the first frame and a part of a distance measurement range set in the second frame may overlap with the other. In other words, in Step S110, a distance measurement range may be set so that the distance measurement range set in Step S110 may overlap with a distance measurement range set in Step S10, at a part. In this case, in Step S10 and Step S110, the distance measurement ranges of the first and second frames may be set so that the width of each of the distance measurement ranges of the first and second frames is identical. For example, a distance measurement range of the first distance measurement segment in group A may be set to 8 m to 13 m, a distance measurement range of the first distance measurement segment in group B may be set to 11 m to 16 m, and a distance measurement range of the second distance measurement segment in group A may be set to 14 m to 19 m, for example. In the above cases, the width of the distance measurement range is 5 m. The distance measurement ranges of the distance measurement segments temporally adjacent to each other (e.g., the first distance measurement segment and the second distance measurement segment in group A) may be set so as not to overlap with each other in the first frame and the second frame.

### [1-3. Effect]

As mentioned above, the distance image obtaining method includes the setting step in which a plurality of distance-divided segments are set in a depth direction (Step S10), and an image capturing step in which a distance image is obtained based on the set distance-divided segments. The image capturing step includes a first distance image group capturing step in which a plurality of distance images are obtained by imaging a part of a plurality of distance-divided segments (Step S20 to Step S90), and a second distance image group capturing step in which a plurality of distance images are obtained by imaging distance-divided segments in a phase different from the part of the plural distance-divided segments (Step S110 to Step S190).

With the above step, a part of the distance-divided segments is differentiated from each other in the two distance images, thereby obtaining two distance images in which distance-divided segments are partially different from each other, without decreasing the resolution of an image. If one of the two distance images is obtained by performing the image capturing in a shorter distance than the other, for example, a distance image obtained by performing the image capturing in a broad range from a short distance to a long distance can be obtained. In the first distance image group capturing step, a distance image is obtained in a part of the distance-divided segment set in Step S10, thereby obtaining a distance image in a shorter period in comparison with a case where distance images are obtained in all of the distance-divided segments. In the distance image obtaining method according to the present disclosure, information regarding a distance to an object, i.e., a distance image, can be quickly obtained with highly accurate resolution in a broad range from a short distance to a long distance.

A plurality of distance-divided segments may have continuity in the depth direction.

Thus, a distance image obtained through the first distance image group capturing step and a distance image obtained through the second distance image group capturing step include images for the same distance. An object positioned in this distance can be detected by using two images, thereby improving the detection accuracy.

A plurality of distance-divided segments may not have the continuity in the depth direction.

Thus, the distance measurement ranges are discretely set in each of the first distance image group capturing step and the second distance image group capturing step, thereby increasing the speed of processing in the first distance image group capturing step and the second distance image group capturing step. Therefore, a distance image can be obtained more quickly.

In addition, two or more distance-divided segments contained in the first distance image group capturing step and two or more distance-divided segments contained in the second distance image group capturing step can be displaced from each other by a half segment. The half segment may be a half of the first distance measurement segment corresponding to a first segment capturing image, for example.

Accordingly, two distance image groups that are displaced by a half segment can be obtained as information regarding a distance to a target. The target is detected by using such two distance image groups, thereby improving the detection accuracy.

The image capturing step includes a distance image group capturing step performed N (an integer more than or equal to 3) times or more. Two or more distance-divided segments contained in each of the distance image group capturing steps may be displaced, from one another, by 1/N segment.

Accordingly, N distance image groups, which are displaced from one another by 1/N segment, can be obtained as information regarding a distance to a target. The target is detected by using such N distance image groups, thereby improving the detection accuracy.

A plurality of distance-divided segments set in the setting step are set so that segments in the front side in the depth direction have a narrower distance measurement range than a segment in the back side in the depth direction. The narrow distance measurement range means that the width of the distance measurement segment is narrow.

Accordingly, a distance to a target near image sensor 122 can be obtained in detail. Therefore, information regarding a distance to the target can be obtained with highly accurate resolution.

As mentioned above, distance detection device 100 includes: image sensor 122 in which pixels each having an APD are arranged in a two-dimensional manner; light source 110 that emits emission light to a target subjected to the image capturing; calculator 140 that treats images captured in image sensor 122; controller 130 that controls light source 110, image sensor 122, and calculator 140; compositor 160 that composes images treated by calculator 140; and outputter 170 that adds predetermined information to the composed image to output the image. Controller 130 sets a plurality of distance-divided segments in the depth direction and controls light source 110, image sensor 122, and calculator 140, to thereby obtain the first distance image group including a plurality of distance images in which a part of the set plural distance-divided segments is imaged, and to obtain second distance image group including a plurality of distance images in which distance-divided segments in a phase different from that of the part of the distance-divided segments are imaged.

With this configuration, effects same as those obtained by the image obtaining method are exhibited. Accordingly, distance detection device 100 can quickly obtain information regarding a distance to a target, i.e., a distance image, with highly accurate resolution in a broad range from a short distance to a long distance.

Image sensor 122, upon obtainment of each of the first distance image group and the second distance image group, stores a pixel signal corresponding to the number of photons detected by pixel 122a in a storage element provided in a circuit of pixel 122a as a pixel voltage, and reads out the stored pixel voltage toward calculator 140. If the pixel voltage exceeds a threshold value in each the obtainment of the first distance image group and the second distance image group, calculator 140 determines that a target is present in the distance image in which the pixel voltage exceeds the threshold value. Compositor 160 generates a three-dimensional distance image from the first distance image group and the second distance image group. Outputter 170 adds, to the three-dimensional distance image, colors that are different from one another and set to each of the first distance image group and the second distance image group.

With this configuration, pixel 122a (pixel circuit) for embodying distance detection device 100 can be miniaturized. In addition, a distance image by which the detection result of a target can be easily visible can be outputted.

Distance detection device 100 further includes CDS circuit 126 (correlated double sampling circuit) that outputs a pixel signal read out from pixel 122a, from image sensor 122 after removing a noise. During a period in which a pixel signal of pixel 122a in the nth line among two-dimensionally arranged pixels 122a undergoes noise removal, CDS circuit 126 outputs a pixel signal of pixel 122a in the n-1th line, to which the noise removal is completed before such a period.

With this configuration, the noise removal from a pixel signal and outputting of the pixel signal from which noise is removed can be performed in parallel, thereby obtaining information regarding a distance to a target, i.e., a distance image, more quickly.

Compositor 160 may preferentially select the determination result of a distance image in the near side in the depth direction, if calculator 140 determines that a target is present in a plurality of distance images in the single pixel 122a for each of the first distance image group and the second distance image group. Outputter 170 may add a color to the selected distance image.

Accordingly, if it is determined that a target is present in a plurality of distance images, a detection result that the target is present in the distance measurement segment nearest to image sensor 122 among a plurality of distance measurement segments respectively corresponding to the plurality of distance images can be outputted. If distance detection device 100 is installed in a vehicle and so on, for example, the vehicle can be driven more safely.

As mentioned above, the distance detection method is used in distance detection device 100 in which pixels 122a each having the APD are two-dimensionally arranged. The distance detection method includes a first distance detection step (e.g., Steps S10 to S100) in which a distance to a target is detected in the first frame, and a second distance detection step (e.g., Steps S110 to S200) in which a distance to the target is detected in the second frame following the first frame. The first distance detection step includes a first setting step (Step S10) and a first distance-measurement step (Step S20). In the first setting step, distance measurement ranges that are different from one another and have no distance continuity from one another are individually set to each of a plurality of subframes that are obtained by dividing the first frame and are included in group A. In the first distance-measurement step, distance measurement is performed in the distance measurement ranges set in the first setting step, in each of the subframes in group A. The second distance detection step includes a second setting step (Step S110) and a second distance measurement step (Step S120). In the second setting step, distance measurement ranges that are not set in the first setting step are individually set to a plurality of subframes that are obtained by dividing the second frame and are included in group B. In the second distance measurement step, distance measurement is performed in the distance measurement ranges set in the second setting step.

With these steps, the first distance image and the second distance image have no continuity in terms of the distance measurement range. Accordingly, the first distance image and the second distance image can be generated in a shorter period, in comparison with a case in which a measurement range in distance detection device 100 is set for each of the first distance image and the second distance image. The second distance image corresponds to an image in a distance measurement range missed in the first distance image. The continuity of the distance measurement ranges can be secured by generating the first distance image and the second distance image alternately. With the distance detection method according to the present embodiment, distance detection device 100 that can obtain information regarding a distance to a target more quickly with highly accurate resolution in a broad range from a short distance to a long distance, while securing the continuity in the distance measurement ranges (distance continuity).

In the second setting step, a distance measurement range is set so that a part of a distance measurement range overlaps with a distance measurement range set in the first setting step.

With such setting, the distance measurement range can be prevented from missing in the first distance image and the second distance image.

In the first distance measurement step, a first voltage signal corresponding to a photon detected by the APD is outputted to the exterior of pixel 122a in each of the subframes in group A. The first distance detection step includes a first determination step (Step S60) and the first distance image generation step (Step S100). In the first determination step, the presence/absence of an object is determined in accordance with the first voltage signal in each of the subframes in group A. In the first distance image generation step, the determination results for the respective subframes in group A are composed to generate the first distance image. In the second distance measurement step, a second voltage signal corresponding to the photon detected by the APD is outputted to the exterior of pixel 122a in each of the subframes in group B. The second distance detection step includes a second determination step (Step S160) and the second distance image generation step (Step S200). In the second determination step, the presence/absence of an object is determined in accordance with the second voltage signal in each of the subframes in group B. In the second distance image generation step, the determination results for the respective subframes in group A (e.g., the second distance image group) are composed to generate the second distance image.

With this configuration, the number of components, for performing the processing, to be added to pixel 122a in distance detection device 100 can be reduced, thereby miniaturizing the pixel circuit.

In the first distance image generation step, if it is determined for a single pixel 122a, in the first determination step, that an object is present in two or more subframes in group A among subframes in group A, a first distance image is generated in accordance with the determination result for the subframe in which the distance is measured in a distance measurement range in a shorter distance, among the two or more subframes in group A. In the second distance image generation step, if it is determined for a single pixel 122a, in the second determination step, that an object is present in two or more subframes in group B among subframes in group B, a second distance image is generated in accordance with the determination result for the subframe in which the distance is measured in a distance measurement range in a shorter distance, among the two or more subframes in group B.

Accordingly, when the distance detection method is used for a use application that places importance to information regarding a short distance between information regarding a long distance and that regarding the short distance (e.g., for an automobile), a distance image suitable for the use application can be generated.

The first distance detection step and the second distance detection step each include the CDS processing step and the output step. In the CDS processing step, correlated double sampling processing is performed to the first voltage signal outputted from pixel 122a, and the processed signal is held. In the output step, a first voltage signal that: is obtained prior to the first voltage signal processed in the CDS processing step; has undergone the correlated double sampling processing; and has been held, is outputted. The CDS processing step and the output step are performed in parallel.

Accordingly, while noise is removed from the first voltage signal in a subframe, another first voltage signal of a subframe, which is previously obtained, can be read out, thereby further improving the frame rate.

As mentioned above, distance detection device 100 includes image sensor 122 (an example of a light receiver) in which pixels 122a each having the APD are arranged in a two-dimensional manner, and controller 130 that controls image sensor 122. Controller 130 causes image sensor 122 (an example of the light receiver) to respectively set distance measurement ranges that are different from one another and have no distance continuity from one another to a plurality of subframes that are obtained by dividing the first frame and are included in group A, and to perform distance measurement in the set distance measurement range in each of the subframes in group A. Controller 130 also causes image sensor 122 to respectively set distance measurement ranges that are not set in the setting for the first frame to a plurality of subframes that are obtained by dividing the second frame following the first frame and are included in group B different from group A, and to perform distance measurement in the set distance measurement range for each of the subframes in group B.

With this configuration, effects same as those obtained by the above-mentioned distance detection method are exhibited. Specifically, an apparent frame rate for generating a distance image can be improved, according to distance detection device 100.

Each of pixels 122a has integration circuit 124 and output circuit 125. Integration circuit 124 integrates electric charge generated due to the detection of the photon by the APDs in each of the subframes in group A and each of the subframes in group B. Output circuit 125 outputs the detection-integration value output signal (an example of the voltage signal) based on the integrated value integrated by integration circuit 124 in each of the subframes in group A and each of the subframes in group B. Distance detection device 100 further includes calculator 140 and compositor 160. Calculator 140 determines the presence/absence of an object in a subframe in accordance with the detection-integration value output signal outputted from output circuit 125, in each of the subframes in group A and each of the subframes in group B. Compositor 160 generates a first distance image corresponding to the first frame in accordance with the determination result by calculator 140 for pixel 122a in each of the subframes in group A, and generates a second distance image corresponding to the second frame in accordance with the determination result by calculator 140 for pixel 122a in each of the subframes in group B.

With this configuration, pixel 122a (pixel circuit) for embodying distance detection device 100 can be miniaturized.

### Embodiment 2

### [2-1. Configuration]

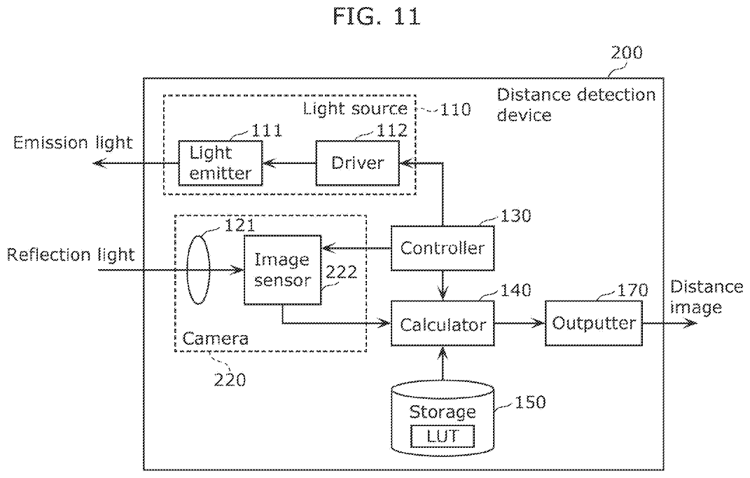

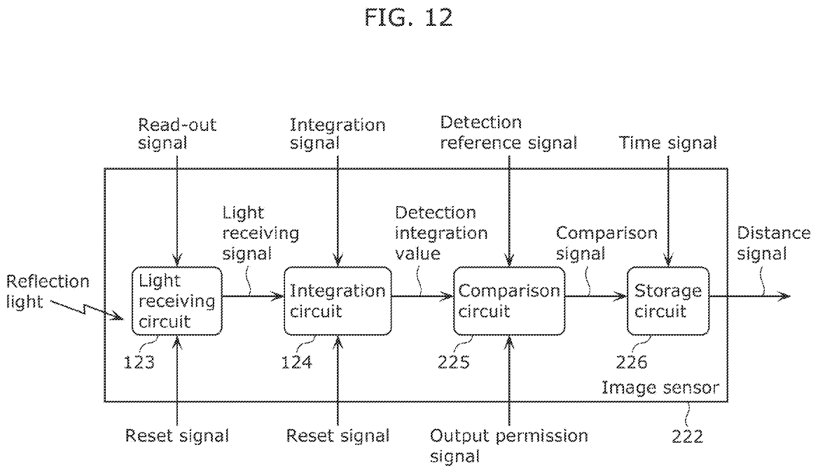

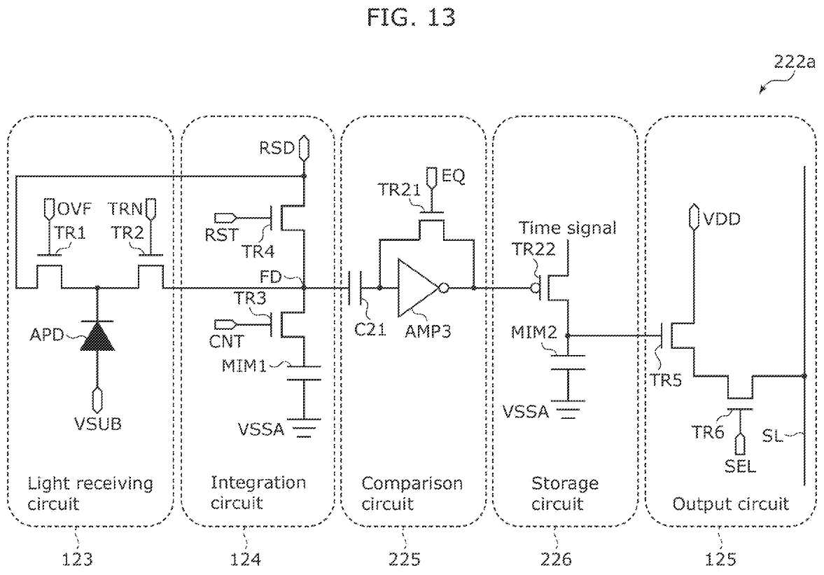

First, configuration of a distance detection device according to the present embodiment is described, with reference to FIGS. 11 to 13. FIG. 11 is a block diagram showing a configuration of distance detection device 200 according to the present embodiment. FIG. 12 is a block diagram showing a configuration of image sensor 222 according to the present embodiment. FIG. 13 is a circuit diagram showing a configuration of pixel 122a according to the present embodiment. A difference from distance detection device 100 according to Embodiment 1 is mainly described hereinafter. The same configuration is allocated by the same reference, and the description for the same configuration may be omitted or simplified.

As shown in FIG. 11, distance detection device 200 according to the present embodiment includes camera 220 in place of camera 120 included in distance detection device 100 according to Embodiment 1. Distance detection device 200 according to the present embodiment does not include compositor 160. In FIG. 12, output circuit 125 is not shown.

As shown in FIG. 12, image sensor 222 has comparison circuit 225 and storage circuit 226 which are added to image sensor 122 according to Embodiment 1. Hereinafter, specific configuration and function of the two blocks are described with reference to FIG. 13. The specific configuration described hereinafter shows one example, so that the configuration of pixel 222a is not limited to the configuration below. For example, other configurations having the similar functions as the present embodiment can exhibit the similar effects as the present embodiment.

Comparison circuit 225 compares a detection integration value from integration circuit 124 with a threshold value, and outputs a comparison signal that is to be turned ON when the detection integration value is greater than the threshold value, to a control terminal (e.g., a gate terminal) of transistor TR22 in storage circuit 226. Comparison circuit 225 has capacitor C21, transistor T21 and inverter AMP3.

Capacitor C21 is a direct-current cutting capacitor for removing a direct-current component from a signal (detection integration value) outputted from integration circuit 124. Capacitor C21 is connected between an output terminal of integration circuit 124 and an input terminal of inverter AMP3.

Transistor TR21 is a switching transistor (a clamp transistor) for equalizing inverter AMP3, and is connected between an input terminal and an output terminal of inverter AMP3. Equalization signal EQ inputted to the control terminal (e.g., a gate terminal) of transistor TR21 controls the conduction and non-conduction of transistor TR21. When equalization signal is turned ON, transistor TR21 is conducted and inverter AMP3 is equalized.

Inverter AMP3 outputs a comparison signal in accordance with the detection integration value generated in integration circuit 124. Inverter AMP3 has the input terminal connected to integration circuit 124 via capacitor C21, and the output terminal connected to a control terminal (e.g., gate terminal) of transistor TR22. Inverter AMP3 is connected to a power source (not shown) that supplies a predetermined voltage to inverter AMP3 as a power source voltage.

When an input voltage to inverter AMP3 increases, for example, an output voltage from inverter AMP3 decreases to a low level. The input voltage to inverter AMP3 varies by a voltage of integration circuit 124, and thus varies due to presence/absence of a photon incident in the APD. Accordingly, inverter AMP3 outputs signals (comparison signals) different from one another in a signal level, in accordance with the presence/absence of the incident photon. If a voltage of electric-charge accumulation capacitor MIM1. decreases to a predetermined voltage or lower (i.e., the photon is incident in the APD), the comparison signal is turned ON. Turning ON of the comparison signal causes a signal with a high-level voltage value to be outputted.

Furthermore, comparison circuit 225 may set a threshold value according to the detection integration value inputted from integration circuit 124, when a detection reference signal (see FIG. 12) outputted under control by controller 130. Comparison circuit 225 has a function of turning the comparison signal that is an output signal into an ON state, when the detection integration value to be inputted is greater relative to a set threshold value. An output permission signal may be inputted to comparison circuit 225. In such a case, only when the output permission signal is turned ON, the comparison signal is turned ON.

Upon receiving a time signal having an output value that varies depending on distance measurement periods (e.g., a time signal corresponding to a distance measurement period, by comparison circuit 225 and integration circuit 124), storage circuit 226 stores, as a distance signal, the time signal at a time point when the comparison signal is turned ON. Storage circuit 226 includes transistor TR22 and storage capacitor MIM2. Specifically, transistor TR22 has a drain connected to a terminal for application of the time signal, and a source connected to negative power source VSSA through storage capacitor MIM2. To this terminal, the time signal is applied under the control by controller 130. The time signal is a signal (voltage) corresponding to the distance signal. The time signal is set to be a voltage in one-to-one correspondence with “k” of the kth distance measurement period (“k” is any of natural numbers). In other words, the time signal is set to be a voltage in one-to-one correspondence with each of the distance measurement period. The time signal has a RAMP waveform by which a voltage sweeps for each of the distance measurement periods, for example. Transistor TR22 is a P-type transistor, for example. Storage capacitor MIM2 is an example of a storage element that is provided in a circuit of pixel 222a and stores a time signal voltage.

Transistor TR22 has a control terminal (e.g., a gate terminal) to which the comparison signal outputted from comparison circuit 225 is inputted. With this configuration, the time signal (i.e., a voltage) at the time when the comparison signal is turned ON is stored in storage capacitor MIM2.

Output circuit 125 amplifies a voltage of the distance signal and outputs the amplified voltage signal to signal line SL. Output circuit 125 outputs the voltage signal after the completion of the distance measurement in a plurality of distance measurement periods in the first frame. It should be noted that the same processing is performed in the second frame.

Compositor 160 may preferentially select the determination result of a segment distance image at the near side in the depth direction, if calculator 140 determines that a target is present in a plurality of (two or more) segment distance images in one pixel 222a for each of the first distance image group and the second distance image group. Outputter 170 may add a color to pixel 222a of the selected segment distance image among a plurality of segment distance images.

### [2-2. Operation]

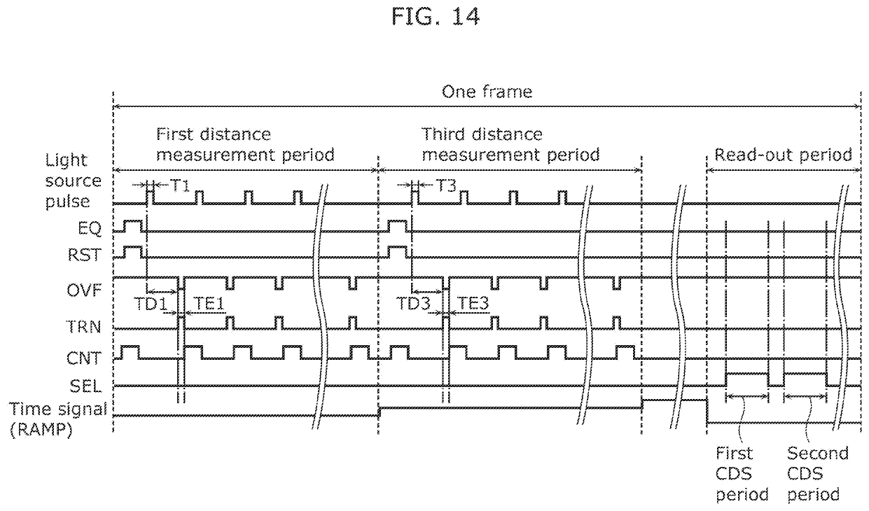

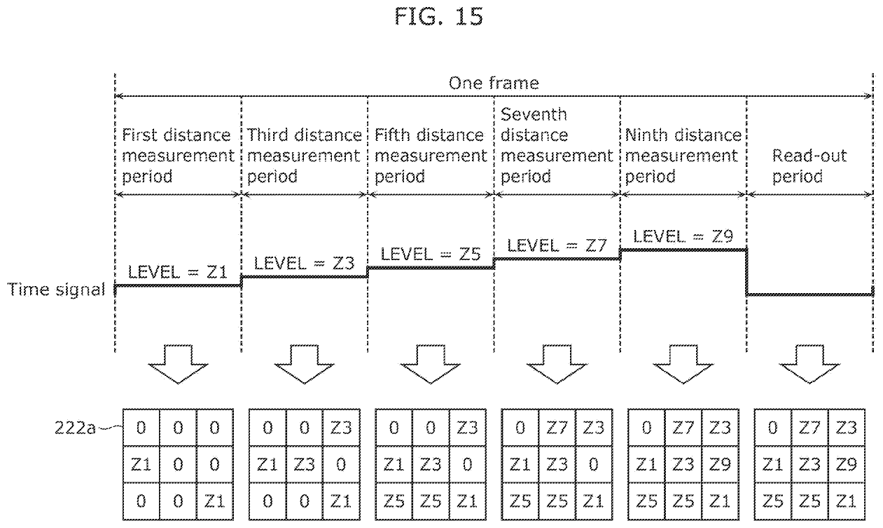

Next, operations of generating distance images in distance detection device 200 as mentioned above is described. First, schematic operations of generating a distance image in distance detection device 200 is described, with reference to FIGS. 14 and 15. FIG. 14 is a diagram showing timings of measurement processing in distance detection device 200 according to the present embodiment. FIG. 15 is a diagram for describing a distance image in a single frame according to the present embodiment.

Controller 130 determines distance measurement ranges in the first and second frames that are different from each other, in a manner that a distance measurement range in the first frame and a distance measurement range in the second frame are different from each other. Then, controller 130 divides the first frame into a plurality of distance measurement periods and respectively sets the measurement ranges that are different from one another and have no distance continuity, to the distance measurement periods. FIGS. 14 and 15 shows a case where the first frame is divided into five distance measurement periods (the first distance measurement period, the third distance measurement period, the fifth distance measurement period, the seventh distance measurement period, and the ninth distance measurement period). FIG. 14 shows the first distance measurement period and the third distance measurement period among the five distance measurement periods.

As shown in FIG. 14, a single frame includes a plurality of distance measurement periods and one read-out period. In the present embodiment, a voltage signal is not read out for each distance measurement period. In the first distance measurement period, distance measurement is performed in a distance measurement range in the shortest distance.

As shown in FIGS. 13 and 15, in the first distance measurement period, a time signal having a signal level (voltage) of Z1 is inputted to the drain of transistor TR22. At this time, if the detection integration value from integration circuit 124 is greater than the threshold value, the comparison signal is turned ON. The comparison signal is turned ON, causing transistor TR22 not to be conducted. Thus, the signal level Z1 inputted to the drain of transistor TR22 up to this time is stored in storage capacitor MIM2 of storage circuit 226 included in pixel 222a. Storage capacitor MIM2 in such pixel 222a keeps the signal level Z1 until being reset. A circuit configuration for resetting storage capacitor MIM2 is not shown in FIG. 13.

FIG. 15 shows an example in which transistor TR22 in each of two pixels 222a is not conducted, and the signal level Z1 is stored in storage capacitor MIM2 of each of the two pixels 222a, during the first distance measurement period. The signal level Z1 is stored, so that an object exists in the distance measurement range corresponding to the distance measurement period. In other words, pixel 222a according to the present embodiment can determine whether an object exists in a pixel circuit. The signal level Z1 stored in storage capacitor MIM2 can be a signal (distance signal) indicating a distance to the object. FIG. 15 shows “0”, which means that transistor TR22 is not in an OFF state in pixel 222a.

Next, the distance measurement is performed in a third distance measurement period. In the third distance measurement period, distance measurement is performed in a distance measurement range in the shortest distance but a distance measurement range of the first distance measurement period, among a plurality of distance measurement periods included in the first frame. Controller 130 causes light source 110 and camera 120 to sequentially perform distance measurement, starting from a distance measurement period with the distance measurement range in a shorter distance, for example.

As shown in FIGS. 13 and 15, in the third distance measurement period, a time signal having a signal level (voltage) of Z3 is inputted in the drain of transistor TR22. At this time, if the detection integration value from integration circuit 124 is greater than the threshold value, the comparison signal is turned ON. The comparison signal is turned ON, causing transistor TR22 not to be conducted. Thus, the signal level Z3 inputted in the drain of transistor TR22 up to this time is stored in storage capacitor MIM2 of storage circuit 226 included in pixel 222a. Storage capacitor MIM2 keeps the signal level Z3 until being reset.

FIG. 15 shows an example in which transistor TR22 in each of two pixels 222a is not conducted in the third distance measurement period, and the signal level Z3 is stored in storage capacitor MIM2 of each of two pixels 222a.

Description is given to a case in which the APD in one pixel 222a receives reflection light in each of the first distance measurement period and the third distance measurement period. Electric-charge accumulation capacitor MIM1 is not reset between the first distance measurement period and the third distance measurement period. In the first distance measurement period, it is assumed that the APD generates electric charge according to the photon, the electric charge is accumulated in electric-charge accumulation capacitor MIM1, and the comparison signal from inverter AMP3 is in a turned-ON state. Then, in the third distance measurement period, the APD generates electric charge according to the photon, the electric charge is further accumulated in electric-charge accumulation capacitor MIM1. Here, even if the electric charge is still further accumulated, the comparison signal from inverter AMP3 remains in the turned-ON state. This causes transistor TR22 in pixel 222a to remain in the non-conductive state. As a result, a signal level stored in storage capacitor MIM2 remains as Z1. As mentioned above, pixel 222a may be controlled so that the signal level (an example of the determination result) for a distance measurement range in a short distance is preferentially processed.

Specifically, controller 130 causes light source 110 and camera 220 to sequentially perform distance measurement, starting from a distance measurement period with the distance measurement range in a short distance, among a plurality of distance measurement periods in group C, in the first distance measurement step corresponding to Step S30 in FIG. 8. In addition, controller 130 causes light source 110 and camera 220 to sequentially perform distance measurement, starting from a distance measurement period with the distance measurement range in a short distance, among a plurality of distance measurement periods in group D, in the second distance measurement step corresponding to Step S140 in FIG. 8.

Distance measurement is subsequently performed in the fifth distance measurement period, the seventh distance measurement period, and the ninth distance measurement period, which are included in the first frame, in the same manner as above. Upon completion of the distance measurement in each of the distance measurement periods configuring the first frame, reading-out of a time signal (distance signal) starts. In other words, time signals obtained in a plurality of distance measurement periods are read out by a single reading-out processing. A time period for the reading-out can be shortened in comparison with a case where the reading-out processing is performed in each distance measurement period, for example. Calculator 140 converts a signal level (voltage) of the time signal to a distance. Calculator 140 converts the voltage to a distance value based on LUT (e.g., the LUT stored in storage 150 in FIG. 11) in which voltage and distance values are associated with each other, to generate a distance image, for example.

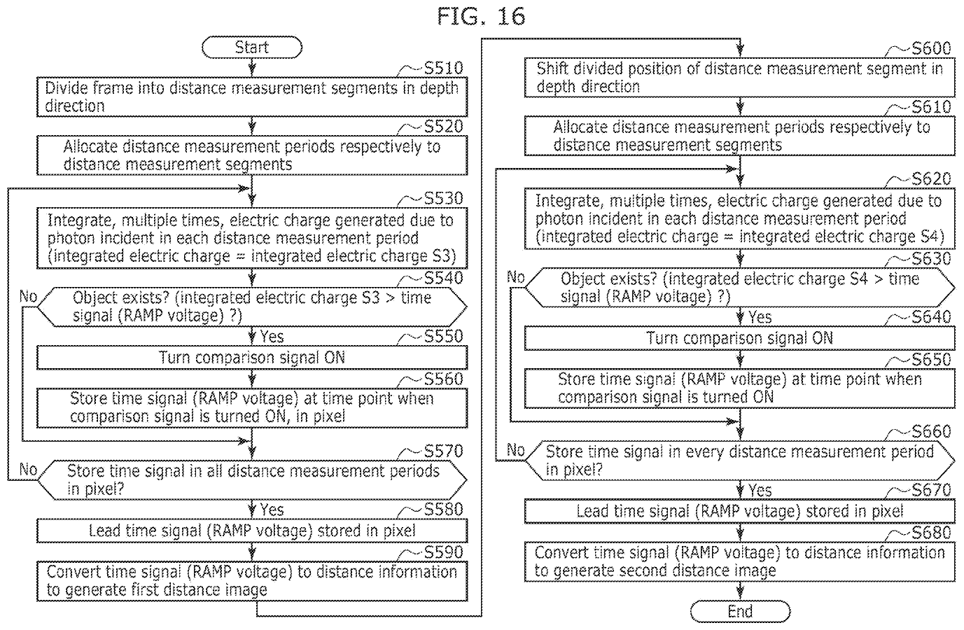

Here, operations of generating a distance image in distance detection device 200 is described. FIG. 16 is a flowchart showing an example of distance image generation processing in distance detection device 200 according to the present embodiment. Processing from Step S510 to Step S590 described below is one example of the first distance detection step in which distance to an object is detected in the first frame. Processing from Step S600 to Step S680 described below is an example of the second distance detection step in which distance to the object is detected in the second frame. Processing in Step S510 shown below is an example of the setting step, processing from Steps S520 to S580 is an example of the first distance image group capturing step, and processing from Step S600 to S670 is an example of a second distance image group capturing step. The first distance image group capturing step and the second distance image group capturing step are included in the image capturing step. Step S510 and Step S600 in FIG. 16 respectively correspond to Step S10 and Step S100 in FIG. 8, so that the description for these steps is simplified.

As shown in FIG. 16, controller 130 divides the distance to be measured into distance measurement segments in the depth direction (Step S510). The number of the division is not particularly limited. Step S510 is an example of a first division step.

Then, controller 130 respectively allocates distance measurement periods to the distance measurement segments (Step S520). The distance measurement period is set depending on a distance of the distance measurement segment. The distance measurement periods are included in group C. Step S520 is an example of the first setting step. The distance measurement periods of group C are a part of the distance measurement segments set in Step S510.

Then, controller 130 captures a distance image for each distance-measurement period in group C. Controller 130 causes light source 110 and camera 220 to measure a distance in the set distance measurement range for each of the plurality of the distance measurement periods in group C.

Distance measurement is performed, to thereby integrate, multiple times, electric charge generated due to photon incident in each distance measurement period (Step S530). The integrated electric charge is also described as integrated electric charge S3. Capturing a distance image in this step corresponds, for example, to obtainment of the integrated electric charge S3 of the distance image. The integrated electric charge S3 corresponds to the detection integration value shown in FIG. 12. In addition, the integrated electric charge S3 is accumulated in electric-charge accumulation capacitor MIM1. Thus, when reflection light based on the emission light emitted from light source 110 enters the APD, the electric charge generated due to the detection of photon by the APD (generated electric charge) is accumulated in electric-charge accumulation capacitor MIM1. Step S530 is an example of the first distance measurement step.

Then, comparison circuit 225 determines the presence/absence of an object based on the accumulated electric charge S3 and a time signal (e.g., RAMP voltage) for each distance measurement period in group C (Step S540). For example, comparison circuit 225 compares integrated electric charge S3 with the time signal. If the accumulated electric charge S3 is greater than the time signal (Yes in Step S540), comparison circuit 225 causes a comparison signal to be turned ON (Step S550). The state in which the comparison signal is turned ON indicates that an object is present. If the integrated electric charge S3 is less than or equal to the time signal (No in Step S540), comparison circuit 225 causes the processing to advance to Step S570. Step S540 is an example of the first determination step.

Storage circuit 226 stores, in pixel 222a (specifically, storage capacitor MIM2), a time signal at the time when the comparison signal is turned ON, as a first distance signal, among time signals having different output values for the respective distance measurement periods in group C (Step S560). Specifically, the first distance signal is stored in storage capacitor MIM2. The first distance signal contains information regarding a distance in relevant pixel 222a.

Then, controller 130 determines whether time signals for all the distance measurement periods in group C are stored in pixel (Step S570). If controller 130 determines that the time signals in all the distance measurement periods in group C are stored in a pixel (Yes in Step S570), compositor 160 leads the time signal (RAMP voltage) stored in pixel 222a (Step S580). Accordingly, calculator 140 can obtain the determination result of each pixel 222a by a single read-out operation in the first frame.

Calculator 140 converts the obtained time signal (RAMP voltage) to distance information to thereby generate a first distance image (Step S590). Step S590 is an example of the first distance image generation step.

Determining that the determination in all the distance measurement periods in group C is not completed (No in Step S570), controller 130 causes the processing to return to Step S530 and to be continued from Step S530 to Step S560 until the determination in all the distance measurement periods in group C is completed.

Subsequently, processing of generating a second distance image in a second frame is performed. The second distance image is generated in accordance with results of distance measurement performed in distance measurement ranges that have not undergone the distance measurement upon generating the first distance image.

Controller 130 causes a divided position (divided distance) of the distance measurement segment to be shifted from the distance measurement segment set in Step S10, in the depth direction (Step S600). Controller 130 can set a distance measurement segment in a phase different from that of the distance measurement segment set in Step S10. Controller 130 can also divide the second frame into a plurality of distance measurement segments. Controller 130 may set non-continuous distance measurement ranges respectively to distance measurement segments in group D. Step S600 is an example of a second division step. Distance measurement periods in group D correspond to the distance measurement segments shifted in Step S600.

Then, controller 130 respectively allocates the distance measurement periods to the distance measurement segments (Step S610). The distance measurement periods are included in group D. Step S620 is an example of the second setting step.

Then, controller 130 captures a distance image for each distance measurement period in group D. Controller 130 causes light source 110 and camera 220 to measure the distance in each of the distance measurement ranges set in Step S610 for the respective distance measurement periods in group D.

Camera 220 integrate, multiple times, electric charge generated due to the photon incident in each distance measurement period (Step S620). The integrated electric charge is also described as integrated electric charge S4. Integrated electric charge S4 corresponds to the detection integration value shown in FIG. 12. In addition, the integrated electric charge S4 is accumulated in electric-charge accumulation capacitor MIM1. Step S620 is an example of the second distance measurement step.

Then, comparison circuit 225 determines the presence/absence of an object in accordance with the accumulated electric charge S4 and a time signal (e.g., RAMP voltage) for each distance measurement period in group D (Step S630). Comparison circuit 225 compares integrated electric charge S4 with the time signal, for example. If the integrated electric charge S4 is greater than the time signal (Yes in Step S630), comparison circuit 225 causes the comparison signal to be turned ON (S640). If the integrated electric charge S4 is less than or equal to the time signal (No in Step S630), comparison circuit 225 causes the processing to advance to Step S660. Step S630 is an example of the second determination step.

Storage circuit 226 stores, in pixel 222a (specifically, storage capacitor MIM2), a time signal at the time when the comparison signal is turned ON, as the first distance signal, among time signals having output values different from one another depending on the respective distance measurement periods in group D (Step S650). Specifically, the first distance signal is stored in storage capacitor MIM2. The first distance signal contains information regarding a distance in pixel 222a.

Then, controller 130 determines whether time signals for all the distance measurement periods in group D are stored in the pixel (Step S660). Determining that the time signals for all the distance measurement periods in group D are stored in a pixel (Yes in Step S660), controller 130 leads the time signal (RAMP voltage) stored in pixel 222a (Step S670). Accordingly, calculator 140 can obtain the determination results of each pixel 222a by a single read-out operation in the second frame.

Calculator 140 converts the obtained time signal (first distance signal) to distance information to thereby generate a second distance image (Step S680). Step S680 is an example of the second distance image generation step.

Determining that the determination in all the distance measurement periods in group D is not completed (No in Step S660), controller 130 causes the processing to return to Step S620 and to be continued from Steps S620 to S650 until the distance measurement in all the distance measurement periods in group D is completed.

The distance detection device 200 repeatedly performs processing from Step S510 to Step S670 shown in FIG. 16. In other words, the first distance image and the second distance image are alternately generated. Specifically, controller 130 causes light source 110 and camera 220 to alternately generate the first distance image and the second distance image. Accordingly, outputter 170 can output the first distance image and the second distance image, alternately.

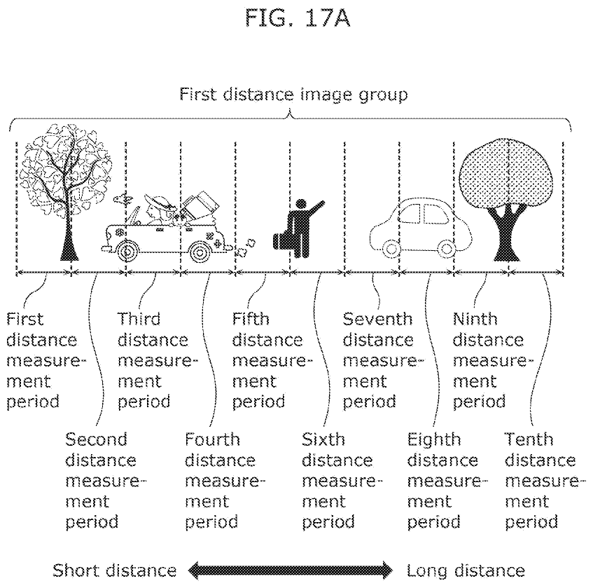

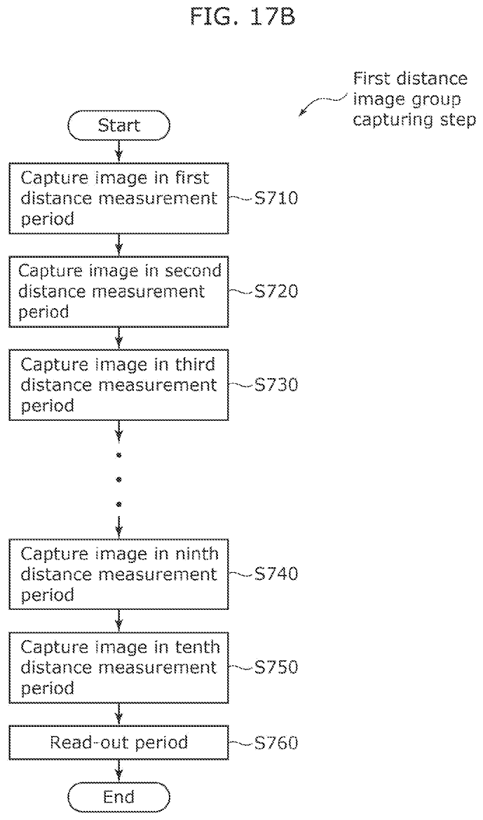

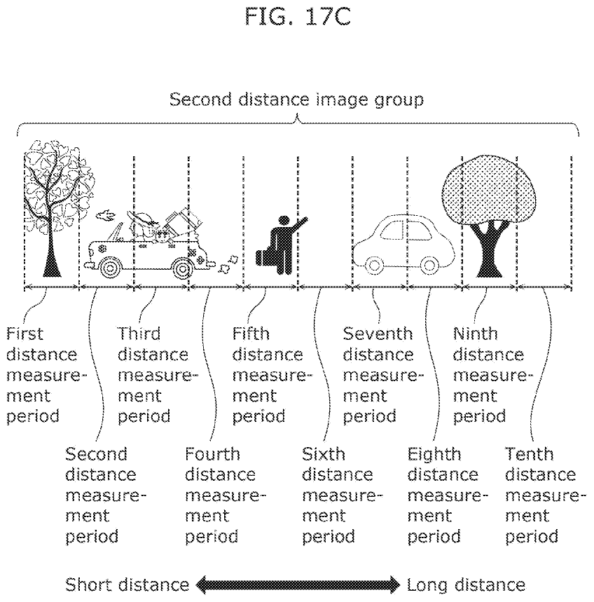

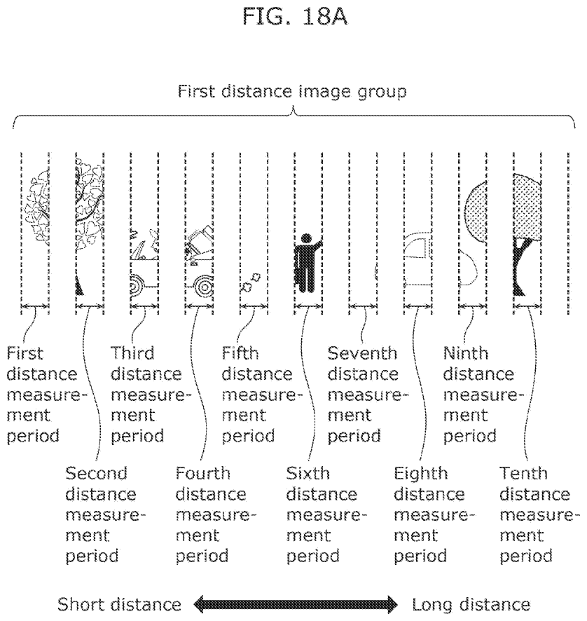

Hereinafter, the first distance image generated in the first frame and the second distance image generated in the second frame are described with reference to FIGS. 17A to 17C. FIG. 17A is a pattern diagram for describing an example of the first distance image according to the present embodiment. FIG. 17B is a flowchart typically showing flow of generating the first distance image according to the present embodiment. FIG. 17B shows processing performed in Steps S530 to S580 shown in FIG. 16. FIG. 17C is a pattern diagram for describing an example of the second distance image according to the present embodiment. FIGS. 17A and 17C show objects detected in the respective distance measurement periods.

As shown in FIG. 17A, the first distance image group includes segment distance images in the respective first to tenth distance measurement periods. For example, a first distance measurement period corresponding to the first segment distance image and a second distance measurement period corresponding to the second segment distance image are continuous distance measurement periods. Distance measurement periods in the first distance image group may be identical to each other (e.g., 1 msec). FIG. 17A shows an example in which distance measurement segments corresponding to the first to tenth segment distance images, among distance measurement segments set in Step S510, are set as distance measurement segments in frame C.

As shown in FIG. 17B, image sensor 222 first performs the image capturing in the first distance measurement period to the tenth distance measurement period (Step S710 to Step S750), and thereafter a read-out period starts (Step S760). Processing in Step S710 corresponds to processing in Step S520 and Step S530 in the first distance measurement period, and processing in Step S720 corresponds to processing in Step S520 and Step S530 in the second distance measurement period. Step S710 is an example of the first segment distance image capturing step. Step S710 corresponds to processing in the first distance measurement period, and Step S720 corresponds to processing in the second distance measurement period. Step S760 corresponds to processing to be performed during the first read-out period.

As shown in FIG. 17C, the second distance image group includes segment distance images in the respective first to tenth distance measurement periods. For example, a first distance measurement segment corresponding to the first segment distance image and a second distance measurement segment corresponding to the second segment distance image are continuous distance measurement segments. Distance measurement segments in the second distance image group may be identical to each other (e.g., 1 msec). In addition, the first distance measurement segment in the second distance image group and the first distance measurement segment in the first distance image group each are allocated with the respective distance measurement periods at least a part of which are different from each other. In other words, at least a part of the first distance measurement period in the second distance image group and at least a part of the first distance measurement period in the first distance image group overlap each other.

As mentioned above, the distance measurement periods in the first distance image group and the second distance image group are set so that at least a part of the distance-measurement periods in each of the first and second distance image groups overlap with each other. Accordingly, even if distance measurement is not accurately performed in one of the first distance image group and the second distance image group, distance measurement performed in the other one of the distance image groups compensates the inaccurate distance measurement. Thus, measurement accuracy is improved. In addition, the distance measurement periods are varied for each distance image groups, thereby enabling the distance measurement in a broad range from a short distance to a long distance without decreasing the resolution.

A part of the first distance measurement period in the second distance image group may overlap with one of the distance measurement periods in the first distance image group.

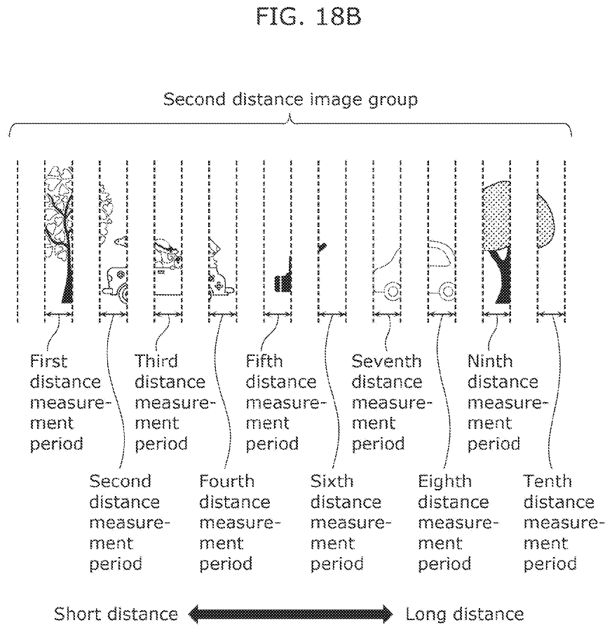

Here, setting of distance measurement segments in each distance image groups is described, with reference to FIGS. 18A and 18B. FIG. 18A is a pattern diagram for describing another example of the first distance image according to the present embodiment. FIG. 18B is a pattern diagram for describing another example of the second distance image according to the present embodiment. FIGS. 18A and 18B show a case in which the distance measurement periods in each of groups C and D are set as non-continuous distance measurement periods.

As shown in FIG. 18A, the first distance image group includes segment distance images in the respective first to tenth distance measurement periods. For example, a first distance measurement period corresponding to the first segment distance image and a second distance measurement period corresponding to the second segment distance image are non-continuous distance measurement periods.

As shown in FIG. 18B, the second distance image group includes a segment distance image in each of the first distance measurement period to a tenth distance measurement period.

For example, a first distance measurement period corresponding to the first segment distance image and a second distance measurement period corresponding to the second segment distance image are non-continuous distance measurement periods.

As mentioned above, distance measurement periods with the distance measurement ranges having no distance continuity may be set. In other words, distance measurement periods having no distance continuity may be set.

As shown in FIGS. 18A and 18B, the first distance image and the second distance image may compensate a missing distance measurement range together with each other. Such a first distance image is generated in accordance with the result of distance measurement performed in a predetermined distance measurement period (e.g., 1 msec) with every such a predetermined distance measurement period (e.g., 1 msec), in the range of the distance measurement periods within which distance detection device 200 can perform distance measurement.

Here, each distance measurement period is 1 msec and the read-out period is 3.3 msec, for example. In the present embodiment, each of the first frame and the second frame is composed of ten distance measurement periods, and thus the frame velocity of a single frame is 13.3 msec (the frame rate is 75 fps). Meanwhile, if all of 20 distance measurement periods in a single frame are subjected to the distance measurement as a comparative example, the frame velocity of the single frame is 23.3 msec (the frame rate: 43 fps). Therefore, an apparent frame rate can be improved in the present embodiment.

[2-3. Effects and so on]

As mentioned above, if the voltage of a pixel signal corresponding to the number of the photon detected by pixel 222a having the APD in each the first distance image group and the second distance image group exceeds a threshold value, image sensor 222 in distance detection device 200 stores a time signal voltage corresponding to the distance image in a storage element in the circuit of pixel 222a (e.g., storage capacitor MIM2). Outputter 170 adds colors, which are different from each other, respectively set to the first distance image group and the second distance image group, each of which includes a distance image obtained by converting the time signal voltage stored in the storage element.

Accordingly, a signal processing amount in the exterior of pixel 222a (e.g., processor in calculator 140 and so on) can be reduced, thereby improving the frame rate in generating a distance image. Accordingly, information regarding a distance to a target can be obtained further quickly.

As mentioned above, the distance detection method is performed in distance detection device 200 in which pixels 222a each having the APD are arranged in a two-dimensional manner. The distance detection method includes the first distance detection step (Steps S510 to Step S590) in which a distance to a target is detected in the first frame, and the second distance detection step (Step S600 to S680) in which the distance to the target is detected in the second frame following the first frame. The first distance detection step includes the first setting step (Step S520) and the first distance-measurement step (Step S530). In the first setting step, distance measurement periods that are different from one another and individually correspond to distance measurement ranges having no distance continuity from one another are respectively set to the plural distance measurement segments that are obtained by dividing the first frame and are included in group C. In the first distance-measurement step, the distance measurement is performed in the distance-measurement period set in the first setting step in each of the plural distance measurement periods in group C. The second distance detection step includes the second setting step (Step S610) and the second distance-measurement step (Step S620). In the second setting step, distance measurement periods that are not set in the first setting step are individually set to the plural distance measurement segments that are obtained by dividing the second frame and are included in group D different from group C. In the second distance-measurement step, the distance measurement is performed in the distance-measurement period set in the second setting step in each of the plural distance measurement periods in group D.

In the first distance measurement step, electric charge generated due to the detection of the photon by the APD is accumulated as accumulated electric charge S3 (an example of first accumulated electric charge) for each of the plural distance measurement periods in group C (Step S530); accumulated electric charge S3 is compared with each of the time signals having output values different depending on the respective distance measurement periods in group C (Step S540); a comparison signal to be turned ON when accumulated electric charge S3 is greater than the time signal is outputted (Step S550); each pixel 222a stores the time signal obtained at the time point when the comparison signal is turned ON (Step S560); and the stored time signal is outputted to the exterior or pixel 222a after the distance measurement in each of the plural distance measurement periods in group C (Step S580). The first distance detection step includes a first distance image generation step (Step S590) in which the first distance image is generated based on the time signal in each of plural pixels 222a.

In the second distance measurement step, electric charge generated due to the detection of a photon by the APD is accumulated as accumulated electric charge S4 (an example of second accumulated electric charge) for each of the plural distance measurement periods in group D (Step S620); accumulated electric charge S4 is compared with each of the time signals having output values different depending on the respective distance measurement periods in group D (Step S630); a comparison signal to be turned ON when accumulated electric charge S4 is greater than the time signal is outputted (Step S640); each pixel 222a stores the time signal obtained at the time point when the comparison signal is turned ON (Step S650); and the stored time signal is outputted to the exterior of pixel 222a after the distance measurement in each of the plural distance measurement periods in group D (Step S670). The second distance detection step includes the second distance image generation step (Step S680) in which the second distance image is generated based on the time signal in each of plural pixels 222a.

Accordingly, a signal processing amount in the exterior of pixel 222a (e.g., processor in calculator 140 and so on) can be reduced, thereby simplifying a system in distance detection device 200.

In the first distance measurement step, distance measurement is sequentially performed starting from a distance measurement period with the distance measurement range in a short distance, among a plurality of distance measurement periods in group C. In the second distance measurement step, distance measurement is sequentially performed starting from a distance measurement period with the distance measurement range in a short distance, among a plurality of distance measurement periods in group D.

Therefore, a distance image can be generated with placing the importance on the information regarding the short distance among information regarding a long distance and the short distance. Accordingly, when the distance detection method is used for a use application placing the importance on the information regarding a short distance, a distance image appropriate for the use application can be generated.

As aforementioned, each of pixels 222a in distance detection device 200 includes: integration circuit 124 in which electric charge generated due to the detection of the photon by the APD is integrated; comparison circuit 225 that compares integrated electric charge integrated in integration circuit 124 with each of the time signals having output values different depending on the respective distance measurement periods in groups C and D, and outputs a comparison signal to be turned ON when the integrated electric charge is greater than the time signal; storage circuit 226 that stores the time signal obtained at the time point when the comparison signal is turned ON; and output circuit 125 that outputs the time signal stored in storage circuit 226 after the distance measurement is completed in a plurality of the distance measurement periods in group C and after the distance measurement is completed in a plurality of the distance measurement periods in group D. Distance detection device 200 further includes calculator 140 that causes the first distance image to be generated in accordance with the time signal outputted in the first frame and causes the second distance image to be generated in accordance with the time signal outputted in the second frame.

With this configuration, a signal processing amount in calculator 140 can be reduced, thereby simplifying the system in distance detection device 200.

### Other Embodiments

Although the distance detection method and the distance detection device according to the embodiments of the present disclosure are described, the present disclosure is not limited to the embodiments. As long as the gist of the present disclosure is not departed, an embodiment obtained by applying, to the present embodiment, various modifications that can be conceived by a person skilled in the art, or an embodiment obtained by combining components in different embodiments can also be contained within the scope of one or more embodiments.

For example, although in the above embodiments, a pitch (interval) of the distance measurement ranges of a plurality of distance measurement periods and subframes for constructing the first frame and the second frame is identical (i.e., an exposure period is identical), the pitches of the distance measurement ranges may be different from one another.

Although in the above embodiments, controller sets distance measurement ranges having no continuity to the respective distance measurement periods and subframes constituting a single frame, the present disclosure is not limited thereto. The controller may set the distance measurement ranges having no continuity in at least two subframes and two distance measurement periods among a plurality of the subframes and a plurality of the distance measurement periods, for example.

Although in the above embodiments, the controller causes a light source and a camera to sequentially perform distance measurement from a short distance to a long distance, the present disclosure is not limited thereto. The controller may cause a light source and a camera to sequentially perform distance measurement from a long distance to a short distance.

Although in the above embodiments, the outputter outputs a distance image to a device exterior to the distance detection device, the present disclosure is not limited thereto. If the distance detection device includes a display, the outputter may output the distance image to the display.

The use application of the distance detection device described in the aforementioned embodiments and so on is not particularly limited. The distance detection device may be used for a three-dimension measuring device and the like for measuring a three-dimensional shape of a movable body including automobiles and ships, a monitoring camera, a robot autonomously moving with checking the position itself, and an object.

The structural components which constitute a processor, such as the aforementioned controller, calculator, and compositor may be configured in the form of exclusive hardware, or may be embodied by executing a software program suitable for the respective structural components. In such a case, each of the structural components may include an arithmetic processor (not shown) and a storage (not shown) that stores a control program, for example. Examples of the arithmetic processor include a micro processing unit (MPU), a CPU, and the like. Examples of the storage include a memory, such as a semiconductor memory. Each of the structural components may be composed of a single component performing centralized control, or may be composed of a plurality of components cooperating with one another to perform distributed control. The software program may be provided, as an application, by communication through a communication network, such as the Internet, or communication through a mobile communication standard, and so on.

Functional blocks in block diagrams are divided in an exemplary manner. A plurality of functional blocks can be embodied as a single functional block, a single functional block may be divided into a plurality of functional blocks, or a part of the function can be shifted to another functional block. Functions of a plurality of functional blocks having functions analogous to one another may be processed by one hardware or may be processed by software in a parallel manner or a time-sharing manner.

The order of performing the respective steps in each of the flowcharts is shown in an exemplary manner for specifically describing the present disclosure, and may be another order other than the illustrated order. A part of the steps may be performed at the same time (in parallel) of other steps.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

A solid-state imaging device according to the present disclosure can be used for a complementary metal oxide semiconductor (CMOS) image sensor that is usable for an onboard camera and the like, under a circumference in which an object moves (e.g., an object moves at high speed).

1. A distance-image obtaining method, comprising:
(A) setting a plurality of distance-divided segments in a depth direction; and
(B) obtaining a distance image based on each of the plurality of distance-divided segments set, wherein
(B) includes:
(B-1) obtaining a plurality of distance images by imaging two or more of the plurality of distance-divided segments, to obtain a first distance image group; and
(B-2) obtaining a plurality of distance images by imaging distance-divided segments, among the plurality of distance-divided segments, in a phase different from a phase of the two or more of the plurality of distance-divided segments, to obtain a second distance image group.

2. The distance-image obtaining method according to claim 1, wherein the distance-divided segments have continuity in the depth direction.

3. The distance-image obtaining method according to claim 1, wherein the distance-divided segments have no continuity in the depth direction.

4. The distance-image obtaining method according to claim 1, wherein two or more distance-divided segments included in the two or more distance-divided segments imaged in (B-1) are displaced from two or more distance-divided segments included in the distance-divided segments imaged in (B-2) by a half segment, respectively.

5. The distance-image obtaining method according to claim 1, wherein (B) includes obtaining a distance image group, the obtaining being performed N or more times, the N being an integer of three or more, and
the obtaining is performed, in each time, in two or more distance-divided segments which are displaced by 1/N segment, among the plurality of distance-divided segments.

6. The distance-image obtaining method according to claim 1, wherein the plurality of distance-divided segments set in (A) are set to cause a segment in a front side in the depth direction to have a narrower distance range than a segment in a back side in the depth direction.

7. A distance detection device, comprising:
an image sensor in which pixels each having an avalanche photo diode (APD) are arranged in a two-dimensional manner;
a light source that emits emission light to a target to be imaged;
a calculator that processes images obtained by the image sensor;
a controller that controls the light source, the image sensor, and the calculator;
a compositor that generates a composite image by combining the images processed by the calculator; and
an outputter that adds predetermined information to the composite image, and outputs the composite image, wherein
the controller:
sets a plurality of distance-divided segments in a depth direction; and
causes the light source, the image sensor, and the calculator to perform obtainment of a first distance image group including a plurality of distance images obtained by imaging two or more of the plurality of distance-divided segments set, and to perform obtainment of a second distance image group including a plurality of distance images by imaging distance-divided segments, among the plurality of distance-divided segments set, in a phase different from a phase of the two or more of the plurality of distance-divided segments.

8. The distance detection device according to claim 7,
wherein the image sensor stores, as a pixel voltage, a pixel signal corresponding to a total number of a photon detected by a pixel included in the pixels, in a storage element provided in a circuit in the pixel during each of the obtainment of the first distance image group and the obtainment of the second distance image group, and reads out, to the calculator, the pixel voltage stored,
the calculator determines that a target exists in a relevant distance image, when the pixel voltage exceeds a threshold value, in each of the obtainment of the first distance image group and the obtainment of the second distance image group,
the compositor generates a three-dimensional distance image from each of the first distance image group and the second distance image group, and
the outputter adds, to the three-dimensional distance image, colors that are different from each other and respectively set to the first distance image group and the second distance image group.

9. The distance detection device according to claim 7, further comprising
a correlated double sampling circuit that outputs, from the image sensor, a pixel signal read out from a pixel among the pixels after noise removal,
wherein the correlated double sampling circuit outputs, in a period during which the pixel signal of the pixel in an nth line among the pixels arranged in the two-dimensional manner undergoes the noise removal, a pixel signal of a pixel among the pixels in an n-1th line, which has undergone the noise removal before the period.

10. The distance detection device according to claim 7,
wherein when a voltage of a pixel signal corresponding to a total number of a photon detected by the pixel having the APD exceeds a threshold value, the image sensor stores a time signal voltage corresponding to a distance image in a storage element in a circuit of the pixel, in each of the first distance image group and the second distance image group, and
the outputter adds colors that are different from each other and respectively set to the first distance image group and the second distance image group which include the distance image obtained by converting the time signal voltage stored in the storage element.

11. The distance detection device according to claim 8, wherein
the compositor preferentially selects a determination result of a distance image at a front side in the depth direction, when the calculator determines that the target exists, in a single pixel, in a plurality of distance images among the plurality of distance images in each of the first distance image group and the second distance image group, and
the outputter adds a color included in the colors to the distance image selected.
